(19) United States
(12) Patent Application Publication
(10) Pub. No.: US 2024/0202540 A1
(43) Pub. Date: Jun. 20, 2024

(54) SETTING DEVICE, SETTING METHOD, AND RECORDING MEDIUM

(71) Applicant: NEC Corporation, Minato-ku, Tokyo (JP)

(72) Inventors: Shumpei KUBOSAWA, Tokyo (JP); Takashi ONISHI, Tokyo (JP)

(73) Assignee: NEC Corporation, Minato-ku, Tokyo (JP)

(21) Appl. No.: 18/554,336

(22) PCT Filed: Apr. 20, 2021
(86) PCT No.: PCT/JP2021/016105

§ 371 Date: Oct. 6, 2023

(51) Int. Cl. G06N 3/092; G06F 30/20

(52) U.S. Cl. CPC G06N 3/092; G06F 30/20

(57) ABSTRACT

A setting device sets a parameter value of a simulator that simulates a simulation subject. The setting device calculates weights of respective output items based on an output value of the simulator and a reference output value. The reference output value is subject to simulation according to the output value of the simulator. The setting device controls, by using an evaluation function, learning of a setting of a parameter value of the simulator. The evaluation function is based on the output value of the simulator, the reference output value, and the weights.

### TECHNICAL FIELD

The present invention relates to a setting device, a setting method, and a recording medium.

### BACKGROUND ART

It has been proposed that a parameter value calculation method for a simulator be learned by means of reinforcement learning.

For example, Patent Document 1 discloses learning parameters of a waste incineration plant simulator (numerical values that characterize a plant model of a process model) by means of reinforcement learning (Q-Learning, TD learning method, or the like). Moreover, Patent Document 1 discloses that a reward is determined according to the difference between the measured and calculated state amounts.

### PRIOR ART DOCUMENTS

### Patent Documents

Patent Document 1: Japanese Unexamined Patent Application, First Publication No. 2004-178492

### SUMMARY OF THE INVENTION

### Problems to be Solved by the Invention

It is conceivable that output values of multiple items can be obtained from a simulation subject, such as when a plant includes multiple sensors. In such a case, it is preferable to effectively perform learning of the setting of the parameter values of the simulator.

An example object of the present invention is to provide a setting device, a setting method, and a recording medium capable of solving the problem mentioned above.

### Means for Solving the Problem

According to a first example aspect of the present invention, a setting device includes: a parameter value setting means that sets a parameter value of a simulator that simulates a simulation subject; a weight calculation means that calculates weights of respective output items based on an output value of the simulator and a reference output value, the reference output value being subject to simulation according to the output value of the simulator; and a learning control means that controls, by using an evaluation function, learning of a setting of a parameter value of the simulator by the parameter value setting means, the evaluation function being based on the output value of the simulator, the reference output value, and the weights.

According to a second example aspect of the present invention, a setting device includes: a parameter value setting means that sets a parameter value of a first simulator that simulates a simulation subject: and a learning control means that controls, by using an evaluation function, learning of a setting of the parameter value of the first simulator by the parameter value setting means, the evaluation function being based on an output value of a second simulator that simulates the simulation subject, and an output value of the first simulator obtained when an input value that is same as an input value to the second simulator is entered to the first simulator.

According to a third example aspect of the present invention, a setting method executed by a computer includes: setting a parameter value of a first simulator that simulates a simulation subject: and controlling, by using an evaluation function, learning of a setting of the parameter value of the first simulator, the evaluation function being based on an output value of a second simulator that simulates the simulation subject, and an output value of the first simulator obtained when an input value that is same as an input value to the second simulator is entered to the first simulator.

According to a fourth example aspect of the present invention, a setting method executed by a computer includes: setting a parameter value of a first simulator that simulates a simulation subject: and controlling, by using an evaluation function, learning of a setting of the parameter value of the first simulator, the evaluation function being based on an output value of a second simulator that simulates the simulation subject, and an output value of the first simulator obtained when an input value that is same as an input value to the second simulator is entered to the first simulator.

According to a fifth example aspect of the present invention, a recording medium has recorded therein a program causing a computer to execute: setting a parameter value of a simulator that simulates a simulation subject: calculating weights of respective output items based on an output value of the simulator and a reference output value, the reference output value being subject to simulation according to the output value of the simulator; and controlling, by using an evaluation function, learning of a setting of a parameter value of the simulator, the evaluation function being based on the output value of the simulator, the reference output value, and the weights.

According to a sixth example aspect of the present invention, a recording medium has recorded therein a program causing a computer to execute: setting a parameter value of a first simulator that simulates a simulation subject: and controlling, by using an evaluation function, learning of a setting of the parameter value of the first simulator, the evaluation function being based on an output value of a second simulator that simulates the simulation subject, and an output value of the first simulator obtained when an input value that is same as an input value to the second simulator is entered to the first simulator.

### Effect of Invention

According to the present invention, it is expected that learning of the setting of parameter values of a simulator can be performed effectively when the output values of a plurality of items can be obtained from a simulation subject.

### BRIEF DESCRIPTION OF THE DRAWINGS

FIG. 1 is a diagram showing a device configuration example of a simulation system according to a first example embodiment.

FIG. 2 is a diagram showing a configuration example of a setting device at the time of learning according to the first example embodiment.

FIG. 3 is a diagram showing an example of data input/output at the time of operating the simulation system according to the first example embodiment.

FIG. 4 is a diagram showing a configuration example of a simulation system according to a second example embodiment.

FIG. 5 is a diagram showing an example of data input/output at the time of learning in the simulation system according to the second example embodiment.

FIG. 6 is a diagram showing a configuration example for evaluation value calculation in a setting device according to the second example embodiment.

FIG. 7 is a diagram showing an example of gradients of errors in sensor values according to the second example embodiment.

FIG. 8 is a diagram showing an example of normalized errors calculated by a weight calculation unit according to the second example embodiment.

FIG. 9 is a diagram showing an example of matching degrees calculated by the weight calculation unit according to the second example embodiment.

FIG. 10 is a diagram showing an example of weights calculated by the weight calculation unit according to the second example embodiment.

FIG. 11 is a diagram showing a first example of a weighted error distribution in the second example embodiment.

FIG. 12 is a diagram showing a second example of a weighted error distribution in the second example embodiment.

FIG. 13 is a diagram showing an example of weight update performed by a learning control unit according to the second example embodiment.

FIG. 14 is a diagram showing an example of a processing procedure for updating error weights performed by the setting device according to the second example embodiment.

FIG. 15 is a diagram showing a configuration example of a simulation system according to a third example embodiment.

FIG. 16 is a diagram showing an example of data input/output at the time of learning in the simulation system according to the third example embodiment.

FIG. 17 is a diagram showing an example of gradient vectors in the parameter value space in the third example embodiment.

FIG. 18 is a diagram showing an example of a processing procedure for estimating an error differential dLᵢ(θ)/dθ by means of a gradient vector calculation unit according to the third example embodiment.

FIG. 19 is a diagram showing an example of a processing procedure for updating error weights performed by the setting device according to the third example embodiment.

FIG. 20 is a diagram showing a configuration example of a simulation system according to a fourth example embodiment.

FIG. 21 is a diagram showing an example of data input/output at the time of learning in the simulation system according to the fourth example embodiment.

FIG. 22 is a diagram showing a configuration example of a simulation system according to a fifth example embodiment.

FIG. 23 is a diagram showing an example of data input/output at the time of learning in the simulation system according to the fifth example embodiment.

FIG. 24 is a diagram showing a configuration example of a simulation system according to a sixth example embodiment.

FIG. 25 is a diagram showing an example of data input/output at the time of learning in the simulation system according to the sixth example embodiment.

FIG. 26 is a diagram showing a configuration example of a setting device according to a seventh example embodiment.

FIG. 27 is a diagram showing a configuration example of a setting device according to an eighth example embodiment.

FIG. 28 is a diagram showing an example of a processing procedure in a setting method according to a ninth example embodiment.

FIG. 29 is a diagram showing an example of a processing procedure in a setting method according to a tenth example embodiment.

FIG. 30 is a schematic block diagram showing a configuration of a computer according to at least one example embodiment.

### EXAMPLE EMBODIMENT

Hereinafter, example embodiments of the present invention will be described, however, the present invention within the scope of the claims is not limited by the following example embodiments. Furthermore, all the combinations of features described in the example embodiments may not be essential for the solving means of the invention.

### First Example Embodiment

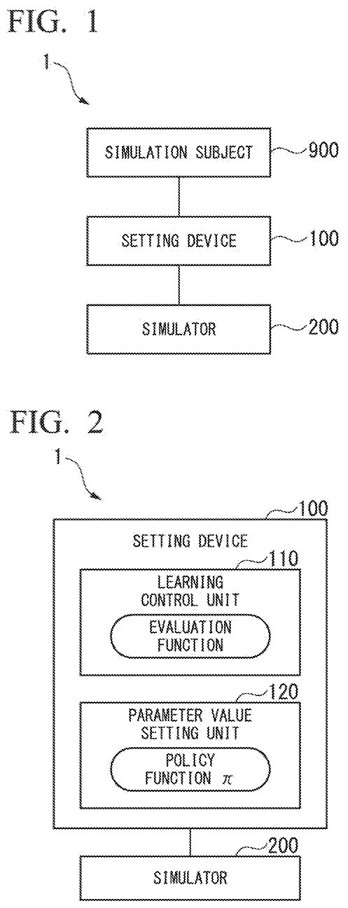

FIG. 1 is a diagram showing a device configuration example of a simulation system according to a first example embodiment.

With the configuration shown in FIG. 1, the simulation system 1 includes a setting device 100 and a simulator 200. Also shown in FIG. 1 is a simulation subject 900. The simulation subject 900 may be included in the simulation system 1 or may be configured outside the simulation system 1.

The simulation subject 900 is a subject of simulation performed by the simulation system 1. The simulation subject 900 may be any simulation subject that can be simulated, and is not limited to a specific simulation subject. Also, the simulation subject 900 may be a system including a plurality of devices, a single device, or a part of a device.

For example, the simulation subject 900 may be, but is not limited to, any of a chemical plant, a distillation column, an air traffic control system, or a railroad system.

The simulation system 1 simulates the simulation subject 900.

Specifically, a simulator 200 includes a simulation model of the simulation subject 900. The simulation model of the simulation subject 900 included in the simulator 200 has a parameter corresponding to the state of the simulation subject 900. By the setting device 100 setting a parameter value for the simulation model, the simulator 200 simulates the behavior of the simulation subject 900 in the state of the simulation subject 900 according to the set parameter value.

Both the setting device 100 and the simulator 200 may be configured using a computer. The setting device 100 and the simulator 200 may be configured as one device including both of them.

The simulation model of the simulation subject 900 included in the simulator 200 is also simply referred to as a simulation model or a simulation model of the simulation subject 900.

The parameter of the simulation model of the simulation subject 900 included in the simulator 200 is also simply referred to as a parameter or the parameter of the simulator 200. The parameter value of the simulation model of the simulation subject 900 included in the simulator 200 is also simply referred to as a parameter value or the parameter value of the simulator 200.

The setting device 100 acquires a reference output value. The reference output value referred to here is a subject value to be simulated by the output value of the simulator 200. The setting device 100 sets the parameter value so that the output value of the simulator 200 matches the reference output value. Specifically, the setting device 100 sets the parameter value so that the output value of the simulator 200 approximates the reference output value as closely as possible.

For example, the same value as an actual input value to the simulation subject 900 may be input to the simulator 200. Then, the setting device 100 may acquire the actual output value of the simulation subject 900 for this input value as the reference output value, and set the parameter value so that the output value of the simulator 200 approximates the reference output value as closely as possible.

Thereby, the simulator 200 can simulate the simulation subject 900 with high accuracy according to the state of the simulation subject 900. Also, by making reference to the parameter value set by the setting device 100, the state of the simulation subject 900 can be analyzed.

In the case where the simulation system 1 acquires an actual input value and output value of the simulation subject 900, the input value and output value of the simulation subject 900 may be acquired in a real-time manner. In such a case, the simulator 200 can simulate the simulation subject 900 in a real-time manner.

Alternatively, the simulation system 1 may acquire historical data of input values and output values of the simulation subject 900. In such a case, the simulator 200 can reproduce through simulation, behaviors of the simulation subject 900 observed in the past.

In such a case, the setting device 100 and the simulation subject 900 need not be connected for communication.

An input value to the simulation subject 900 or a value corresponding to an input value to the simulation subject 900 is also referred to as a control input value. The value corresponding to an input value to the simulation subject 900 may be a value that can be used as an input value to the simulation subject 900 but it may not be scheduled to be actually input to the simulation subject 900.

The simulation system 1 may simulate the simulation subject 900 based on virtual data of the control input value and the reference output value instead of the actual data of the simulation subject 900. For example, the simulation system 1 may simulate the simulation subject 900 based on planned input/output values of the simulation subject 900. Accordingly, by making reference to the parameter value set by the setting device 100, it is possible to analyze the state of the simulation subject 900 suitable for executing the plan.

In such a case, the setting device 100 and the simulation subject 900 need not be connected for communication.

The output value of the simulation subject 900 is not limited to a specific value, as long as it is a value that can be acquired by the simulation system 1. Below, means for acquiring the output value of the simulation subject 900 will be treated as a sensor. The output value of the simulation subject 900 is also referred to as a sensor value.

The output value of the simulation subject 900 may include a sensor value of the simulation subject 900 itself, such as the pressure inside the tank included in the simulation subject 900. Moreover, the output value of the simulation subject 900 may include a sensor value related to the surrounding environment of the simulation subject 900, such as the room temperature of the room in which the simulation subject 900 is installed.

In the case where the simulation subject 900 has a plurality of outputs, each individual output of the simulation subject 900 is also referred to as an output item of the simulation subject 900 or simply an output item. The output value of the simulation subject 900 may be represented by a vector having an element for each output item. When distinguishing the output values of all the output items of the simulation subject 900 from the output value for each output item, the output values of all the output items are also referred to as an output value vector.

As for the simulator 200 that simulates the simulation subject 900, as with the simulation subject 900, the terms “output item” and “output value vector” are used. The terms “output item” and “output value vector” are also used for reference output values. For example, the reference output values of all output items are also referred to as a “reference output value vector”.

The input value to the simulation subject 900 may include a value input to the simulation subject 900 as a signal, such as a fluid flow rate command value in the piping included in the simulation subject 900. Also, the input value to the simulation subject 900 may include a value input by operating the simulation subject 900, such as an opening degree of an adjustment valve operated by the operator of the simulation subject 900.

In the case where there are multiple inputs to the simulation subject 900, each input to the simulation subject 900 is also referred to as an input item to the simulation subject 900. The input value of the simulation subject 900 may be represented by a vector having an element for each input item. When distinguishing the input values of all the input items of the simulation subject 900 from the output value for each input item, the input values of all the input items are also referred to as an input value vector.

The setting device 100 may update the parameter value during a simulation according to the temporal change of the state of the simulation subject 900.

Moreover, the setting device 100 may set the parameter value so that the simulation model exhibits the same behavior as the simulation subject 900 or a behavior that is as similar as possible to the simulation subject 900 even if some of the sensors of the simulation subject 900 fail.

The simulation model of the simulation subject 900 may include multiple parameters, and the values of these multiple parameters may be represented by vectors.

When all parameter values of the simulation model of the simulation subject 900 are distinguished from individual parameter values, all parameter values are also referred to as a parameter value vector.

FIG. 2 is a diagram showing a configuration example of the setting device 100 at the time of learning. In the configuration shown in FIG. 2, the setting device 100 includes a learning control unit 110 and a parameter value setting unit 120.

The setting device 100 acquires the method of simulation model parameter value calculation through reinforcement learning.

Reinforcement learning is a type of machine learning. In reinforcement learning, a “policy” serving as an action decision criterion for an “agent” in an “environment” to observe a “state” and determine an “action”, is a subject of updating performed through learning. When updating a policy, the agent is presented with a “reward” that indicates the evaluation of an action's impact on the environment. In addition to the policy, the reward calculation method may also be subject to learning updating. Also, as a reward, a so-called “loss” may be presented to the agent, indicating that the smaller the value, the higher the evaluation.

Learning is also referred to as training.

In the simulation system 1, the setting device 100 corresponds to an example of an agent. The simulator 200 and the output source of the control input value and the reference output value, such as the simulation subject 900, correspond to examples of the environment. The control input value, the reference output value, and the output value of the simulator 200 correspond to examples of the state observed by the setting device 100.

The parameter value setting unit 120 sets the parameter value of the simulator 200. Specifically, the parameter value setting unit 120 includes a function for calculating the parameter value, and uses this function to calculate the parameter value. The parameter value setting unit 120 transmits the calculated parameter value to the simulator 200 to thereby set the parameter value in the simulator 200.

The parameter value setting unit 120 corresponds to an example of the parameter value setting means.

The criterion for the parameter value setting unit 120 to determine a parameter value may be configured in a form other than a function. For example, the criterion for the parameter value setting unit 120 to determine a parameter value may be configured in a form of an algorithm.

The setting of the parameter value performed by the parameter value setting unit 120 corresponds to an example of the action. The criterion for the parameter value setting unit 120 to determine the parameter value corresponds to an example of the policy.

The criterion for the parameter value setting unit 120 to determine the parameter value is configured to be updatable. For example, if the criterion for the parameter value setting unit 120 to determine the parameter value is configured in the form of a function, the value of a coefficient and constant terms of the function may be updatable. In the case where the parameter value setting unit 120 is configured in the form of an algorithm, the algorithm may include an external variable whose value can be updated by learning.

In the following, an example in which the criterion for the parameter value setting unit 120 to determine the parameter value, is configured in the form of a function, will be described. This function is also referred to as a policy function. The policy function may be denoted by “x”.

The arguments of the policy function π may be, but are not limited to, a control input value, a reference output value, and an output value of the simulator 200. Also, the policy function π may take data for a plurality of times as arguments. For example, the policy function π may take the control input value, the reference output value, and the historical information of the simulator 200 as arguments.

The learning control unit 110 controls learning of parameter value setting performed by the parameter value setting unit 120, using an evaluation function based on the output value of the simulator 200 and the reference output value. The learning control unit 110 corresponds to an example of the learning control means.

Specifically, the learning control unit 110 includes an evaluation function for calculating an evaluation value for the parameter value set by the parameter value setting unit 120, taking the output value of the simulator 200 and the reference output value as arguments. The learning control unit 110 calculates an evaluation value, using this evaluation function.

For example, the learning control unit 110 may use an evaluation function that calculates the magnitude of error in the output value of the simulator 200 with respect to the reference output value as an evaluation value.

The criterion for the learning control unit 110 to determine an evaluation value may be configured in a form other than a function. For example, the criterion for the learning control unit 110 to determine an evaluation value may be configured in the form of an algorithm.

The evaluation value acquired by the learning control unit 110 corresponds to an example of the reward. The learning control unit 110 may acquire a so-called loss as a reward, which indicates that the smaller the value, the higher the evaluation, as in the error mentioned above.

An example in which the learning control unit 110 calculates an evaluation value using an evaluation function will be described below. This evaluation function is also referred to as a reward function.

The learning control unit 110 controls learning of parameter value setting performed by the parameter value setting unit 120 based on the calculated evaluation value. Specifically, the parameter value setting learning performed by the parameter value setting unit 120 here is to update the policy function π.

The learning control unit 110 updates the policy function π so as to reduce the evaluation value. Thereby, the learning control unit 110 updates the policy function π so that the output value of the simulator 200 approximates the reference output value. Instead of the learning control unit 110 directly updating the policy function π, the parameter value setting unit 120 may update the policy function π.

A commonly known method can be used as a method for updating the policy function π here. For example, if the gradient of the policy function π can be calculated by some method such as differentiation or difference approximation of the policy function x, the learning control unit 110 may use a gradient method to determine the update content of the policy function π.

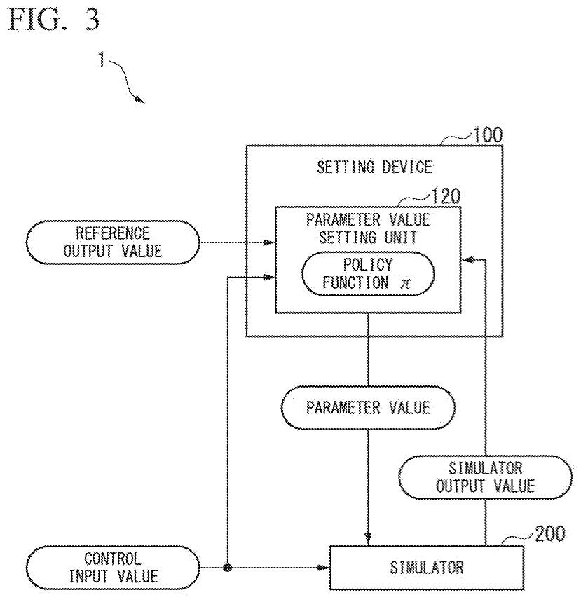

FIG. 3 is a diagram showing an example of data input/output at the time of operating the simulation system 1.

Of the units of the setting device 100, the example of FIG. 3 shows the parameter value setting unit 120. Of the units of the setting device 100 shown in FIG. 2, the learning control unit 110 is unnecessary during operation. The setting device 100 does not have to include the learning control unit 110 during operation. Alternatively, during operation, the setting device 100 may be configured as in the example of FIG. 2, and the learning control unit 110 may be in a stopped state.

In the example of FIG. 3, the parameter value setting unit 120 acquires the control input value, the reference output value, and the output value of the simulator 200. The parameter value setting unit 120 inputs each acquired value to the learned policy function π to calculate the parameter value, and sets the calculated parameter value in the simulator 200.

The simulator 200 executes a simulation of the simulation subject 900 based on the set parameter value, and calculates the output value for the control input value. In the following, the time is represented by a serial number for each time step, such as time 0, 1, 2, . . . . The parameter value setting unit 120 calculates and sets the parameter value for each time step. The simulator 200 calculates the output value for the control input value each time the parameter value is set.

The input/output in the simulator 200 is expressed as in Expression (1).

[Expression 1]

y\hat{ }^{(t+1) =}f(x^{(t)};θ^{(t)} (1)

x^{(t)} represents the input value vector to the simulator 200 at time t. θ^{(t)} represents the parameter value vector of the simulator 200 at time t.

f is a function that indicates the behavior of the simulation model. In function f, the state of the simulation model is indicated by the argument of the parameter value θ^{(t)}.

The simulation model may have states other than the parameter value θ^{(t)}. In such a case, the function f may take a state variable value as an argument in addition to the parameter value θ^{(t)}.

y\hat{ }^{(t+1)} represents the output value vector of the simulator 200 at time t+1.

The simulator 200 may calculate the output value vector y\hat{ }^{(t)} of the simulator 200 at time t, based on x^{(t)} and θ^{(t)}.

Where the simulation start time is 0 and the current time on the simulation is t, the time-series data of the control input value vector from time 0 to τ is expressed as

### Expression (2).

[Expression 2]

x=[x⁽⁰⁾,x⁽¹⁾. . . ,x^{(τ)}] (2)

The time-series data of the output value of the simulation subject 900 from time 0 to τ are expressed as Expression (3).

[Expression 3]

y=[y⁽⁰⁾,y⁽¹⁾, . . . ,y^{(τ)}] (3)

The time-series data of the output value of the simulator 200 from time 0 to τ are expressed as Expression (4).

[Expression 4]

y\hat{ }=[y\hat{ }⁽⁰⁾,y\hat{ }⁽¹⁾, . . . ,y\hat{ }^{(τ)}] (4)

The setting device 100 may use all or some of the time-series data of the control input value, the time-series data of the output value of the simulation subject 900, and the time-series data of the output value of the simulator 200, as state observation data in learning of parameter value setting. The setting device 100 may use virtual data such as time-series data of the planned output value of the simulation subject 900 as the state observation data instead of using the time-series data of the output value of the simulation subject 900.

### Second Example Embodiment

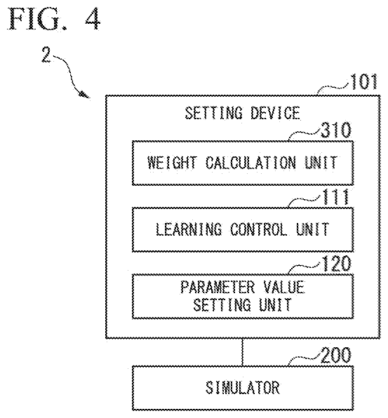

FIG. 4 is a diagram showing a configuration example of a simulation system according to a second example embodiment.

With the configuration shown in FIG. 4, a simulation system 2 includes a setting device 101 and the simulator 200. The setting device 101 includes a learning control unit 111, the parameter value setting unit 120, and a weight calculation unit 310.

Of the units shown in FIG. 4, ones corresponding to those in FIG. 2 and having the same functions are given the same reference signs (120, 200), and detailed descriptions thereof are omitted.

The simulation system 2 corresponds to an example of the simulation system 1. The setting device 101 corresponds to an example of the setting device 100. The learning control unit 111 corresponds to an example of the learning control unit 110. Therefore, the learning control unit 111 corresponds to an example of the learning control means.

The weight calculation unit 310 calculates the weight for the error of the output value of the simulator 200 with respect to the output value of the simulation subject 900 for each output item. The learning control unit 111 uses an evaluation function based on the weight calculated by the weight calculation unit 310 in addition to the output value of the simulator 200 and the reference output value, to calculate an error obtained by weighting and summing the error for each output item as an evaluation value. In other respects, the simulation system 2 is similar to the simulation system 1.

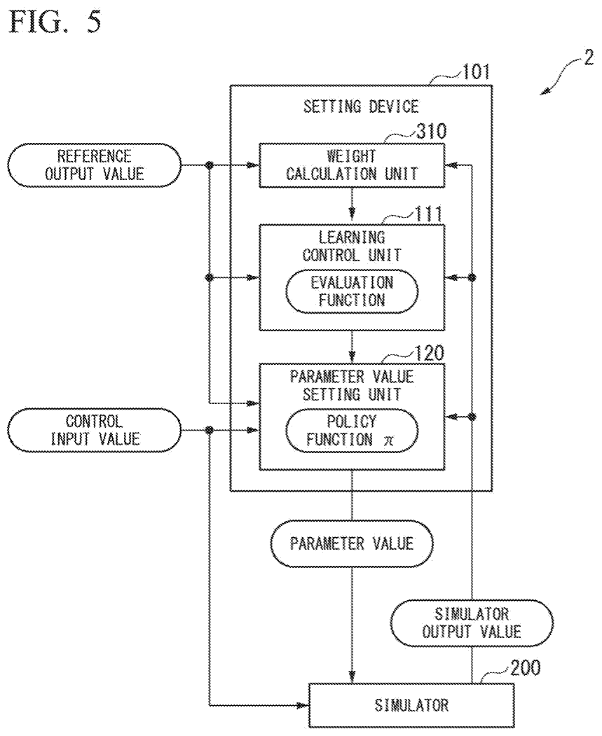

FIG. 5 is a diagram showing an example of data input/output at the time of learning in the simulation system 2. In the example of FIG. 5, the weight calculation unit 310 receives inputs of the reference output value and the output value of the simulator 200, and calculates the weight for each output item.

The learning control unit 111 receives inputs of the reference output value, the output value of the simulator 200, and the weight calculated by weight calculation unit 310. The learning control unit 111 calculates the error of the output value of the simulator 200 with respect to the reference output value for each output item, and weights and sums the error for each output item using the weight calculated by the weight calculation unit 310. The learning control unit 111 uses the weighted sum of errors as an evaluation value and controls the parameter value setting learning performed by the parameter value setting unit 120 so as to reduce the evaluation value.

The parameter value setting unit 120 receives inputs of the control input value, the reference output value, and the output value of the simulator 200. The parameter value setting unit 120 inputs each acquired value to the policy function π to calculate the parameter value, and sets the calculated parameter value in the simulator 200.

The simulator 200 executes a simulation of the simulation subject 900 based on the set parameter value, and calculates the output value for the control input value.

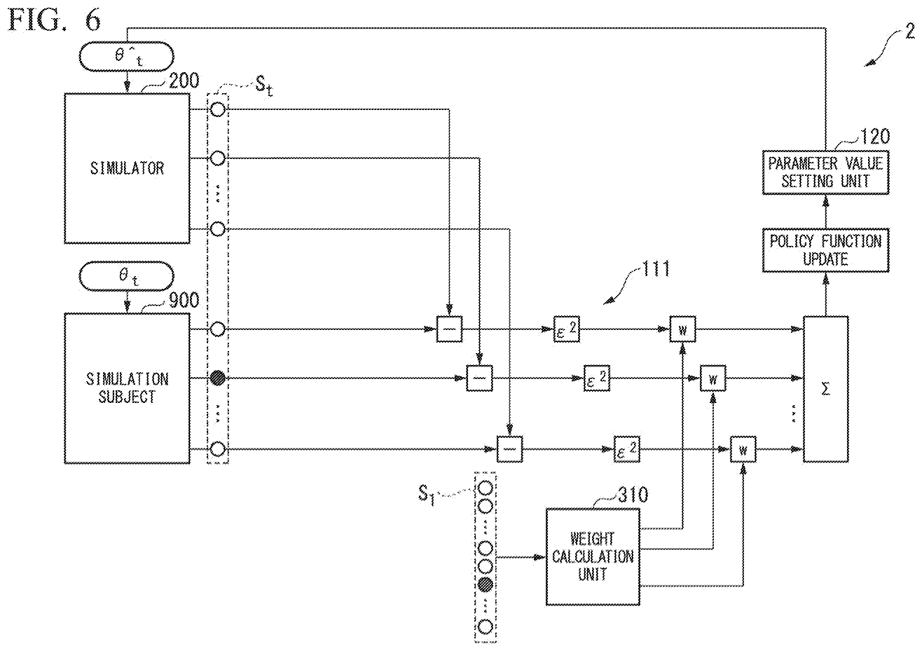

FIG. 6 is a diagram showing a configuration example for evaluation value calculation in the setting device 101.

In the example of FIG. 6, the state of the simulation subject 900 is represented as “θₜ”. The parameter value of the simulator 200 corresponding to the state of the simulation subject 900 is represented as “θ\hat{ }ₜ”.

Sₜ represents the output of sensors of the simulation subject 900 and the output of the simulator 200 simulating the sensors of the simulation subject 900. A white circle (◯) represents that the sensor or output indicated in Sₜ is normal, and a black circle (●) represents that it is failing. FIG. 6 shows an example where one of the sensors of the simulation subject 900 has failed.

The learning control unit 111 calculates, as an evaluation value, the weighted sum of the squares of the difference between the output value of the simulation subject 900 and the output value of the simulator 200 for each output item, and updates the policy function π so as to minimize the evaluation value. The square of the difference for each output item between the output value of the simulation subject 900 and the output value of the simulator 200 is also referred to as a squared error.

“−” in FIG. 6 represents the difference between the output of the simulation subject 900 and the output of the simulator 200 for each output item. “ε²” indicates square. “w” indicates weighting based on the weight calculated by the weight calculation unit 310. “Σ” indicates the sum.

As in the example of FIG. 6, when some sensors of the simulation subject 900 are failing, it is conceivable that the accuracy of simulation performed by the simulator 200 is reduced as a result of the learning control unit 111 controlling learning so that the output value of the simulator 200 matches the output value of the failing sensor.

Also, when some of the sensors of the simulation subject 900 are failing, it is conceivable that the error calculated as an evaluation value cannot be reduced to zero. Since the error cannot be reduced to 0, learning may take time.

Therefore, the weight calculation unit 310 sets a weight for each output item. This weight is used as a weight indicating the degree to which the error of the output value of the simulator 200 with respect to the output value of the simulation subject 900 is reflected on the evaluation value. When the weights of all output items are distinguished from the weight for each output item, the weights of all output items are also referred to as a weight vector.

The weight calculation unit 310 corresponds to an example of the weight calculation means.

The weight calculation unit 310 may set each weight for each output item in the range of 0 or more and 1 or less. In such a case, the weight vector is expressed as Expression (5).

[Expression 5]

wϵ[0,1]^{P} (5)

P is an integer indicating the number of output items. In Expression (5), “[0, 1]” indicates a range of 0 or more and 1 or less.

The parameter value setting unit 120 calculates the parameter value based on, for example, Expression (6).

$$\begin{matrix}[ Expression 6 ] & \\ θ = {argmin}_{{θ}^{( t )}} {\sum }_{t} {\sum }_{i} {{w}_{i} ( {y}_{i}^{( t + 1 )} - {f}_{i} ( {x}^{( t )} ; {θ}^{( t )} ) )}^{2} & ( 6 )\end{matrix}$$

θ indicates time-series data of the parameter value vector. Where the simulation start time is 0 and the current time on the simulation is τ, θ in Expression (6) is expressed as Expression (7).

[Expression 7]

θ=[θ⁽⁰⁾,θ⁽¹⁾, . . . ,θ^{(τ-1)}] (7)

The parameter value setting unit 120 may set the parameter value vector θ^{(τ-1)} at the latest time among the parameter value vectors included in the time-series data shown in Expression (7), to the simulator 200 as the parameter value vector θ(T).
yᵢ^{(t+1)} in Expression (6) indicates the i-th element of the output value vector y^{(t+1)} of the simulation subject 900 at time t+1.
fᵢ(x^{(t)}, θ^{(t)}) indicates a portion of the function f(x^{(t)}, θ^{(t)}) that calculates the output value y\hat{ }ᵢ^{(t+1)} of the simulator 200. y\hat{ }ᵢ^{(t+1)} indicates the i-th element of the output value vector y\hat{ }^{(t+1)} of the simulator 200 at time t+1.
wᵢ indicates the i-th element of the weight vector.
argmin θ^{(t)} is a function that outputs a parameter value vector θ^{(t)} that minimizes the value of the function given as an argument.

It can be expressed as fᵢ(x^{(t)}, θ^{(t)}=y\hat{ }ᵢ^{(t+1)}, and “wᵢ(yᵢ^{(t+1)}−fᵢ(x^{(t)}, θ^{(t)}))²” in Expression 6 indicates the weighted sum of the square error for each output item of the output value of the simulator 200 with respect to the output value of the simulation subject 900. Expression (6) indicates to calculate time-series data of a weight vector, such that the sum of weighted squared errors for output items and weights is minimized.

It should be noted that if all the weights wᵢ in Expression (6) are set to 0, the argument of argmin will always be 0 and cannot be used as an evaluation function in reinforcement learning. The weight calculation unit 310 calculates weights wᵢ under a constraint condition that prevents all weights wᵢ from becoming 0, such as a constraint condition that the sum of all weights wᵢ is 1, for example.

Here, as an example of the case where some of the sensors of the simulation subject 900 are failing, consider a case where the simulation subject 900 includes two sensors and one of the two sensors is failing. The output value of the simulation subject 900 is assumed to be y=[y₁, y₂]=[5.2, 1.2]. It is assumed that the first sensor, that is, the sensor with the output value y₁=5.2, is failing.

The output value of the simulator 200 is y\hat{ }=[y\hat{ }1, y\hat{ }2], and y\hat{ }₁1=1.2 regardless of the parameter value. y\hat{ }2 takes a value in the range of 0.0 or more and 10.0 or less.

The error of the first sensor is a fixed value of y₁-y\hat{ }₁ 1=5.2−1.2=4.0, and the error function value varies depending on the value of y\hat{ }2.

The parameter value vector θ set by the parameter value setting unit 120 is expressed as in Expression (8).

$$\begin{matrix}[ Expression 8 ] & \\ θ = {argmin}_{θ} {\sum }_{i} {{w}_{i} ( {y}_{i} - {f}_{i} ( x ; θ ) )}^{2} & ( 8 )\end{matrix}$$

The error εᵢ of the i-th sensor is given by Expression (9).

[Expression 9]

∈ᵢ=(yᵢ−y\hat{ }i)²≥ (9)

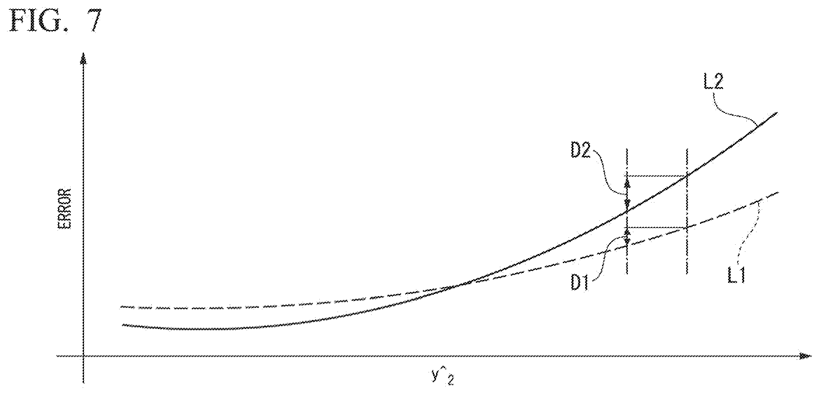

FIG. 7 is a diagram showing an example of gradients of errors in sensor values. The horizontal axis of the graph in FIG. 7 represents the output value y\hat{ }2 of the simulator 200. The vertical axis represents the error Σᵢ(wᵢ(yᵢ−fᵢ(x, θ))²).

The line L1 represents the relationship between the output value y\hat{ }₂ and the error when the weight vector is w=[0.5, 0.5]. The line L2 represents the relationship between the output value y\hat{ }₂ and the error when the weight vector is w=[0.05, 0.95].

In the example of FIG. 7, the error ε₁ of the first sensor takes a fixed value of 9. Therefore, the weighted error w₁ε₁ is a fixed value, and the magnitude of the weighted second sensor error w₂ε₂ determines the magnitude of the error gradient.

Between the line L1 and the line L2, the line L2 with the larger value of the weight w₂ has a greater error gradient. For example, in FIG. 7, the weighted error variation for the same variation of y\hat{ }₂ is greater for D2 than for D1. Since the error gradient is greater, it is expected that the learning time for learning using the gradient method, for example, will be relatively short.

Accordingly, the weight calculation unit 310 calculates the weight based on the normality probability of the sensor value. The normality probability referred to here is a degree to which the sensor value is expected to be accurate. The higher the normality probability, the higher the possibility of the sensor being accurate. Here, the “sensor being accurate” may mean that the sensor value matches the actual value to an extent that the error between the sensor value and the actual value can be ignored.

Specifically, the weight calculation unit 310 normalizes the difference between the output value of the simulation subject 900 and the output value of the simulator 200 for each output item so that they can be compared. Then, the weight calculation unit 310 determines the magnitude of the weight so that the weight of an output item having a larger normalized difference has a smaller magnitude.

As learning progresses and the magnitude of the difference between the output value of the simulation subject 900 and the output value of the simulator 200 becomes smaller, it is conceivable that the difference becomes relatively large in the output item with a low normality probability, such as an output item of a failing sensor or an output item of a sensor with significantly lower accuracy than other sensors. The weight calculation unit 310 determines the magnitude of the weight so that the weight of an output item having a larger normalized difference has a smaller magnitude, and whereby the weight of the output item with a low normality probability is expected to be reduced and the influence thereof on learning is expected to be reduced.

The weight calculation unit 310 may set the initial value of the weight to the same value for all output items. For example, the weight calculation unit 310 may initially set the weight vector w as shown in Expression (10).

$$\begin{matrix}[ Expression 10 ] & \\ w = [ \frac{1}{P} , \frac{1}{P} , ⋯ , \frac{1}{P} ] & ( 10 )\end{matrix}$$

The learning control unit 111 may perform error weighting after learning has progressed to some extent. For example, it may keep the value of each weight at the initial value shown in Expression (10) until learning is performed a predetermined number of times.

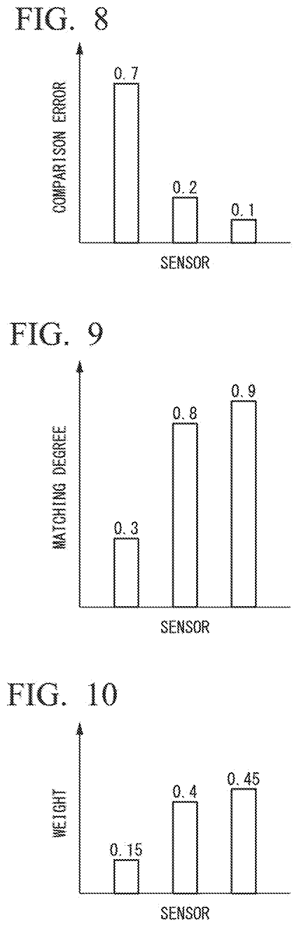

FIG. 8 is a diagram showing an example of normalized errors calculated by the weight calculation unit 310.

The weight calculation unit 310 converts the output value of the simulation subject 900 for each output item, and the output value of the simulator 200 for each output item, so that the range of each sensor is aligned, for example, in a range from 0 to 1 ([0, 1]).

However, the normalization performed by the weight calculation unit 310 is not limited to normalization by means of a specific method as long as the errors are comparable.

The weight calculation unit 310 calculates the squared error of the normalized output value of the simulator 200 with respect to the normalized output value of the simulation subject 900 for each output item. The squared error of the normalized output value of the simulator 200 with respect to the normalized output value of the simulation subject 900 is also referred to as a normalized squared error or a comparison error.

FIG. 8 shows an example in which the number of output items is three. The comparison errors for respective output items are 0.7, 0.2, and 0.1.

FIG. 9 is a diagram showing an example of matching degrees calculated by the weight calculation unit 310.

As the matching degree, a value is used in which the smaller the comparison error, the greater the matching degree.

In the example of FIG. 9, the weight calculation unit 310 calculates the matching degree by subtracting the comparison error from 1 for each output item. The matching degrees for respective output items are 0.3, 0.8, and 0.9. The matching degree for each output item is also expressed as Rᵢ. i is an identification number that identifies an output item, and can be a serial number starting from 1, for example.

However, the method by which the weight calculation unit 310 calculates the matching degree is not limited to the above method.

For example, the weight calculation unit 310 may calculate the matching degree rᵢ for each training sample and for each output item using Expression (11).

$$\begin{matrix}[ Expression 11 ] & \\ 1 \geq {r}_{i} = \frac{{ϵ}_{i}}{{\sum }_{k = 1}^{P} {ϵ}_{k}} \geq 0 & ( 11 )\end{matrix}$$

The training sample referred to here may be a unit of learning for setting the parameter value of the simulator 200. For example, the training samples may include a combination of time-series data of one control input value vector and time-series data of one reference output value vector. The training data may include multiple training samples. When learning is repeatedly performed using one set of training data, one time of learning using one set of training data may be referred to as one-epoch of learning.

In Expression (11), εᵢ represents a normalized squared error.

The weight calculation unit 310 divides the normalized squared error for each output item by the total value of the normalized squared errors using Expression (11), so that each matching degree rᵢ takes a value within the range of 0 or more and 1 or less, and the total value of the matching degrees rᵢ of all output items is 1.

The weight calculation unit 310 may calculate the matching degree Rᵢ for each output item, by averaging the matching degree for each training sample and for each output item, for a predetermined number of training samples using Expression (12), for example.

$$\begin{matrix}[ Expression 12 ] & \\ {R}_{i} = \frac{1}{D} {\sum }_{d = 1}^{D} \frac{{ϵ}_{i}^{( d )}}{{\sum }_{k = 1}^{P} {ϵ}_{k}^{( d )}} ∈ [ 0 , 1 ] & ( 12 )\end{matrix}$$

D is a constant indicating a predetermined number.

εₖ^{(d)} represents the normalized squared error of the k-th output item and the d-th training sample. “εᵢ^{(d)}/Σₖ₌₁^{P}εₖ^{(d)}” indicates the average of D training samples for the matching degree rᵢ for each training sample and for each output item.

Each matching degree Rᵢ takes a value within the range of 0 or more and 1 or less, and the total value of the matching degrees Rᵢ for all output items is 1.

In Expression (12), D may be 1. Therefore, the weight calculation unit 310 may calculate the matching degree rᵢ for each training sample and for each output item calculated by Expression (11), directly as the matching degree Rᵢ for each output item.

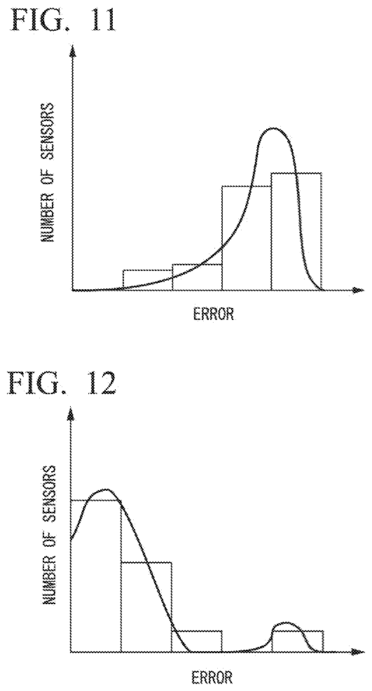

FIG. 10 is a diagram showing an example of weights calculated by the weight calculation unit 310.

The weight calculation unit 310 may multiply the matching degree for each output item obtained in the example of FIG. 9 by the same value so that the sum of the weights becomes one.

For example, the weight calculation unit 310 calculates the weight wᵢ for each output item using Expression (13).

$$\begin{matrix}[ Expression 13 ] & \\ {w}_{i} ← \frac{{R}_{i}}{{\sum }_{k = 1}^{P} {R}_{k}} & ( 13 )\end{matrix}$$

The weight calculation unit 310 calculates the weight for each output item using Expression (13), so that each weight wᵢ falls within the range of 0 or more and 1 or less, and the total value of the weights wᵢ for all output items is 1.

Alternatively, the weight calculation unit 310 may calculate the weight wᵢ for each output item using Expression (14) instead of Expression (13).

$$\begin{matrix}[ Expression 14 ] & \\ {w}_{i} ← {\sum }_{k = 1}^{P} \frac{{e}^{{R}_{i}}}{{e}^{{R}_{k}}} & ( 14 )\end{matrix}$$

e represents the Napier's constant.

The weight calculation unit 310 calculates the weight for each output item using Expression (14), so that each matching degree wᵢ falls within the range of 0 or more and 1 or less, and the total value of the weights wᵢ for all output items is 1.

Moreover, the weight calculation unit 310 calculates a result of an exp exponentiation of a base greater than 1, such as the Napier's number, as shown in Expression (14), thereby emphasizing the relative difference in the magnitude of the matching degree Rᵢ in the weight wᵢ. Specifically, comparing with the case of using Expression (13), when the weight calculation unit 310 uses Expression (14), the weight wᵢ is calculated to be larger as the matching degree Rᵢ increases.

Alternatively, the weight calculation unit 310 may use the matching degree directly as a weight. For example, the weight calculation unit 310 may use the matching degree Rᵢ calculated as in the example of FIG. 9, the matching degree rᵢ calculated using Expression (11), or the matching degree Rᵢ calculated using Expression (12), directly as the weight wᵢ.

The learning control unit 111 may calculate, for each learning unit such as each epoch, an error index value indicating the magnitude of the weighted error between the output value of the simulator 200 and the reference output value in all output items. If the error index value after executing one unit of learning indicates that the error is larger than the error index value before executing the one unit of learning, the learning control unit 111 may set the weight back to the weight before executing the one unit of learning.

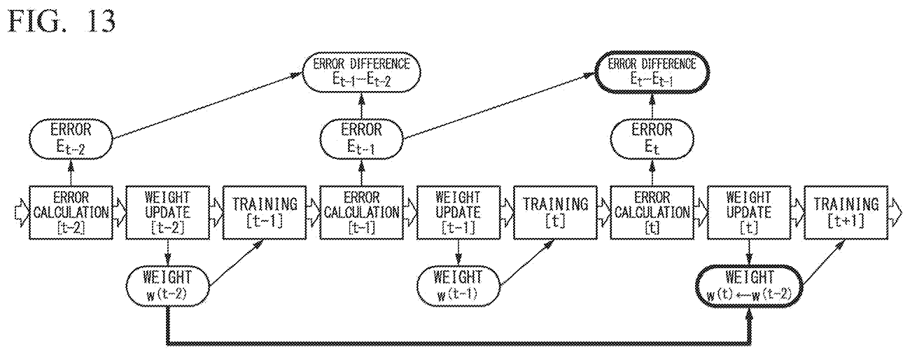

FIG. 11 is a diagram showing a first example of a weighted error distribution.

The horizontal axis of the graph in FIG. 11 represents the class of the magnitude of weighted error in the frequency distribution. The vertical axis represents the number of sensors for each weighted error magnitude class. As the weighted error, a value obtained by multiplying the squared error for each output item of the output value of the simulator 200 with respect to the output value of the simulation subject 900, by the coefficient for each output item calculated by the weight calculation unit 310 can be used.

In the example of FIG. 11, the frequency of classes on the side of the horizontal axis of the graph with relatively large errors (right side of FIG. 11) is relatively large.

FIG. 12 is a diagram showing a second example of a weighted error distribution.

The horizontal axis of the graph in FIG. 12 represents the class of the magnitude of weighted error in the frequency distribution. The vertical axis represents the number of sensors for each weighted error magnitude class.

Comparing with the example in FIG. 11, in the example of FIG. 12, the frequency of classes on the side of the horizontal axis of the graph with relatively small errors (left side of FIG. 12) is relatively large. It can be evaluated that the weighted error is improved in the example of FIG. 12 as compared to the example of FIG. 11.

As the error index value calculated by the learning control unit 111, various index values indicating the degree of improvement of the weighted error can be used. For example, the learning control unit 111 may calculate, as an error index value, the mode value, the average value, or the median value of the squared error of the output value of the simulator 200 with respect to the output value of the simulation subject 900 for all output items: however, it is not limited to these examples.

FIG. 13 is a diagram showing an example of weight update performed by the learning control unit 111. In the example of FIG. 12, the learning control unit 111 performs parameter value setting learning at each time step, calculates the error index value, and updates the weight.

In the example of FIG. 13, the learning control unit 111 uses the difference obtained by subtracting the previous evaluation value from the current evaluation value, as the error index value. “Eₜ” indicates the evaluation value at time t. “Eₜ-Eₜ₋₁” indicates the error index value at time t.

“w^{(t)}” indicates the weight calculated by the weight calculation unit 310 at time t.

As described above, an error obtained by weighting and summing the error for each output item can be used as the evaluation value here.

Also as described above, the learning control unit 111 can use various index values as error index values. For example, the learning control unit 111 may calculate, as an error index value, the mode value, the average value, or the median value of the squared error of the output value of the simulator 200 with respect to the output value of the simulation subject 900 for all output items. Alternatively, the learning control unit 111 may use a difference of a higher evaluation value class such as “|Eₜ−Eₜ₋₁|−|Eₜ₋₁−Eₜ₋₂|” as the error index value.

At time t−1, the error index value is Eₜ₋₁−Eₜ₋₂≥0, and it can be evaluated that the weighted summed error is improved. Therefore, the learning control unit 111 adopts the weight w^{(t-1)} calculated by the weight calculation unit 310 at time t−1.

On the other hand, at time t, the error index value is Eₜ−Eₜ₋₁<0, and it can be evaluated that the weighted summed error is not improved. Therefore, at time t, the learning control unit 111 restores the weight calculation unit 310 to weight w^{(t-2)} calculated by the weight calculation unit 310 at time t−2.

If the error index value indicates that the weighted error is not improving, it is conceivable that the error was not properly weighted.

By restoring the weight as described above, the learning control unit 111 can cancel the possibly inappropriate weight and restore it to the original weight.

If the error index value indicates that the weighted error is not improving, the learning control unit 111 cancels not only the weight but also the learning itself, and restores the parameter value and so forth to the values before learning at that time.

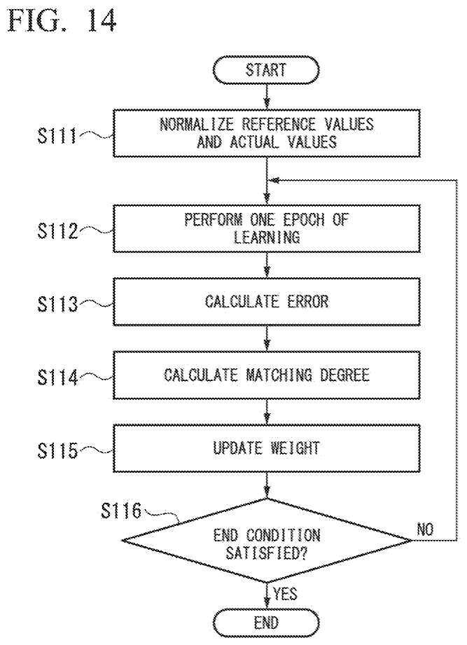

FIG. 14 is a diagram showing an example of a processing procedure for updating error weights performed by the setting device 101.

In the processing of FIG. 14, the learning control unit 111 normalizes the reference output value for each output item and the output value of the simulator 200 for each output item, and sets weights (Step S111). The output value of the simulator 200 is also referred to as the actual value of an output value obtained by simulation.

As described above, the initial value of the weight for each output item can be set to the same value such as 1/P for all output items, for example.

Next, the learning control unit 111 performs learning for one epoch using the set weight (Step S112). However, the amount of learning in Step S112 is not limited to one iteration of learning using one set of training data, and various amounts of unit of learning may be performed.

Next, the weight calculation unit 310 calculates a normalized error of the output value of the simulator 200 with respect to the reference output value for each output item (Step S113). As described above, the weight calculation unit 310 may calculate a normalized squared error as the normalized error.

Next, the weight calculation unit 310 calculates a matching degree of the output value of the simulator 200 with respect to the reference output value for each output item (Step S114). As described above, the weight calculation unit 310 may calculate the matching degree by subtracting from 1 the squared error normalized for each output item. Alternatively, the weight calculation unit 310 may calculate the matching degree using Expression (11). Alternatively, the weight calculation unit 310 may calculate the matching degree using Expression (11) and Expression (12).

Next, the learning control unit 111 updates the weight calculation unit 310 (Step S115). Specifically, the learning control unit 111 updates the weight applied to the error, to the weight calculated by the weight calculation unit 310.

As described above, the weight calculation unit 310 may calculate the weight for each output item using Expression (13) or Expression (14). Alternatively, the weight calculation unit 310 may use the matching degree calculated for each output item directly as a weight for each output item.

As described above, the learning control unit 111 may calculate an error index value. If the error index value indicates that the error is larger than the error index value before executing the one unit of learning, the learning control unit 111 may set the weight back to the weight before executing the one unit of learning.

Next, the learning control unit 111 determines whether or not the end condition of the learning is satisfied (Step S116). The end condition for the learning is not limited to a particular condition. For example, the learning control unit 111 may determine the learning end condition as being satisfied if the learning has been repeated a predetermined number of times. Alternatively, if the evaluation value calculated by the learning control unit 111 indicates that the parameter value is more accurate than a predetermined condition, the learning control unit 111 may determine the learning end condition as being satisfied.

If the learning control unit 111 determines the learning end condition as not being satisfied (Step S116: NO), the processing returns to Step S112.

On the other hand, in Step S116, if the learning control unit 111 determines the learning end condition as being satisfied (Step S116: YES), the setting device 101 ends the processing of FIG. 14.

As described above, the parameter value setting unit 120 sets the parameter value of the simulator 200 that simulates a simulation subject. The weight calculation unit 310 calculates the weight of each output item on the basis of the output value of the simulator 200 and the reference output value that is subject to simulation based on the output value of the simulator 200. The learning control unit 111 controls learning of simulator parameter value setting performed by the parameter value setting means, using an evaluation function based on the output value of the simulator 200, the reference output value, and the weight.

According to the setting device 101, it is possible to set the weight small to reduce the influence thereof on the evaluation value for an output item whose normality probability of the reference output value is low due to a sensor fault or the like. According to the setting device 101, in this respect, it is expected that learning of simulator parameter value setting can be performed effectively when the output values of a plurality of items can be obtained from a simulation subject.

Moreover, the weight calculation unit 310 calculates the weight of each output item such that the weight of the output item having a larger normalized error obtained by normalizing errors of the respective output items has a smaller weight.

According to the setting device 101, when the upper and lower limit values such as sensor range are different for each output item, the upper and lower limit values can be aligned by means of normalization. According to the setting device 101, in this respect, it is expected that weight setting can be performed more appropriately by comparing the magnitude of the error for each output item more appropriately, and that learning of simulator parameter value setting can be performed effectively.

Moreover, the learning control unit 111 calculates an error index value for each unit of learning. The error index value is an index value that indicates the magnitude of the weighted error between the output value of the simulator 200 and the reference output value, for all output items. If the error index value after executing one unit of learning indicates that the error is larger than the error index value before executing the one unit of learning, the learning control unit 111 reverts the weight back to the weight before executing the one unit of learning.

According to the setting device 101, if the error index value indicates that there is a possibility of the weight setting not being appropriate, the weight setting can be reverted to the original setting. According to the setting device 101, in this respect, it is expected that weight setting can be performed highly accurately and that learning of simulator parameter value setting can be performed effectively.

### Third Example Embodiment

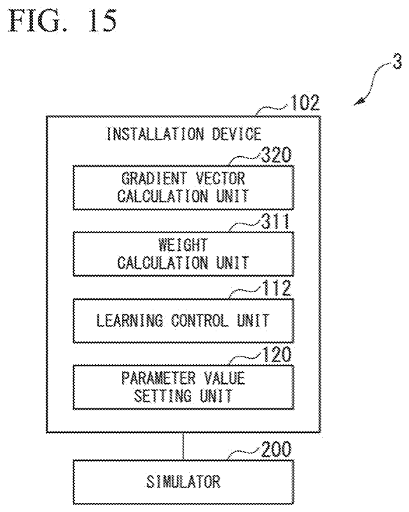

FIG. 15 is a diagram showing a configuration example of a simulation system according to a third example embodiment.

With the configuration shown in FIG. 15, a simulation system 3 includes a setting device 102 and the simulator 200. The setting device 102 includes a learning control unit 112, the parameter value setting unit 120, a weight calculation unit 311, and a gradient vector calculation unit 320.

Of the units shown in FIG. 15, ones corresponding to those in FIG. 2 and having the same functions are given the same reference signs (120, 200), and detailed descriptions thereof are omitted.

The simulation system 3 corresponds to an example of the simulation system 1. The setting device 102 corresponds to an example of the setting device 100. The learning control unit 112 corresponds to an example of the learning control unit 110. Therefore, the learning control unit 112 corresponds to an example of the learning control means.

The weight calculation unit 311 calculates the weight for the error of the output value of the simulator 200 with respect to the output value of the simulation subject 900 for each output item. The learning control unit 112 uses an evaluation function based on the weight calculated by the weight calculation unit 311 in addition to the output value of the simulator 200 and the reference output value, to calculate an error obtained by weighting and summing the error for each output item as an evaluation value. In other respects, the simulation system 3 is similar to the simulation system 1.

The gradient vector calculation unit 320 calculates, for each output item, a gradient vector indicating the gradient of the error between the output value of the simulator 200 and the reference output value in the parameter value space.

The gradient vector calculation unit 320 corresponds to an example of the gradient vector calculation means.

The weight calculation unit 311 calculates the weight for each output item such that the weight increases as the difference between the gradient vector and an average gradient vector obtained by averaging the gradient vectors for all the output items decreases. The weight calculation unit 311 and the weight calculation unit 310 in FIG. 4 use different weight calculation methods. In other respects, the weight calculation unit 311 is the same as the weight calculation unit 310. The weight calculation unit 311 corresponds to an example of the weight calculation means.

Specific learning processing differs between the learning control unit 112 and the learning control unit 111 in FIG. 4, according to the difference in the weight calculation method between the weight calculation unit 311 and the weight calculation unit 310. In other respects, the learning control unit 112 is similar to the learning control unit 111. The learning control unit 112 corresponds to an example of the learning control means.

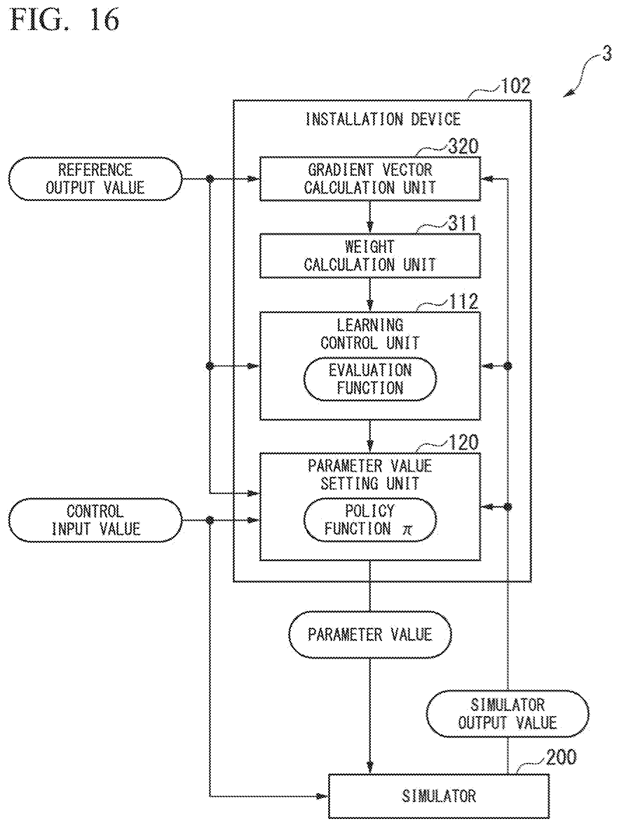

FIG. 16 is a diagram showing an example of data input/output at the time of learning in the simulation system 3. In the example of FIG. 16, the gradient vector calculation unit 320 receives inputs of the reference output value and the output value of the simulator 200, and calculates a gradient vector for each output item.

The weight calculation unit 311 receives the input of the gradient vector for each output item calculated by the gradient vector calculation unit 320, and calculates the weight for each output item.

Data input/output in the learning control unit 112 is the same as in the case of the learning control unit 111 in FIG. 5. The data input/output in the parameter value setting unit 120 is the same as in the case of the parameter value setting unit 120 in FIG. 5. The data input/output in the simulator 200 is the same as in the case of the simulator 200 in FIG. 5.

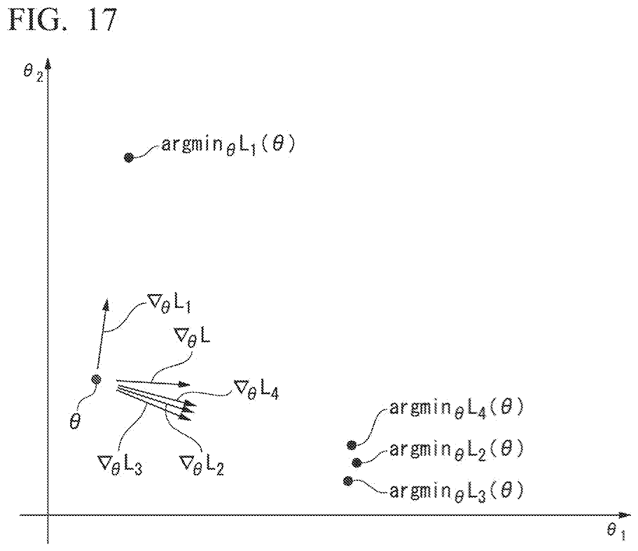

FIG. 17 is a diagram showing an example of gradient vectors in the parameter value space.

FIG. 17 shows an example in which there are two parameters of the simulator 200, namely, θ₁ and θ₂. The horizontal axis of the graph in FIG. 17 represents the value of parameter θ₁. The vertical axis represents the value of parameter θ₂. The orthogonal coordinate space formed by these horizontal and vertical axes corresponds to an example of the parameter value space.

FIG. 17 shows an example in which the number of output items is four and the first sensor out of the four sensors of the simulation subject 900 is failing. Therefore, in the example of FIG. 17, among the elements of the output value vector y=[y₁, y₂, y₃, y₄] of the simulation subject 900, the output value y\hat{ } is different from the normal value of the sensor. On the other hand, the output values y₂, y₃, and y₄ are all taking values that are given when the sensors are normal.

As in Expression (15), the squared error &1 of the output value of the simulator 200 with respect to the output value y₁ of the simulation subject 900 is expressed as L₁(θ) as a function with the parameter θ serving as an argument.

[Expression 15]

ε₁=(y₁−f₁(x;θ))²=L₁(θ) (15)

Also, as in Expression (16), the output value fᵢ(x; θ) of the simulator 200 for each output item is also expressed as y\hat{ }i.

[Expression 16]

fᵢ(x;θ)=y\hat{ }i (16)

Differentiation of the error L₁(θ) with respect to the parameter θ is expressed as in Expression (17).

$$\begin{matrix}[ Expression 17 ] & \\ \frac{d {ℒ}_{1} ( θ )}{d θ} = \frac{d ( {{f}_{1} ( x ; θ )}^{2} - 2 {y}_{1} {f}_{1} ( x ; θ ) )}{d θ} = 2 ( {f}_{1} ( x ; θ ) - {y}_{1} ) \frac{{df}_{1}^{∧} ( x ; θ )}{d θ} & ( 17 )\end{matrix}$$

“y₁” in “2(f₁(x; θ)−y₁)” on the right side of Expression (17) shows a value different from the value given when the sensor is normal, so that the differential dL₁(θ)/dθ of error L₁(θ) with the parameter θ indicates a value different from the value given when the sensor is normal.

Moreover, as in Expression (18), the squared error ε2 of the output value of the simulator 200 with respect to the output value y₂ of the simulation subject 900 is expressed as L₂(θ) as a function with the parameter θ serving as an argument.

[Expression 18]

ε₂=(y₂−f₂(x;θ)²= [symbol] ₂(θ) (18)

Similarly, the squared errors &3 and &4 of the output values of the simulator 200 with respect to the output values y₃ and y₄ of the simulation subject 900 are respectively expressed as L₃(θ) and L₄(θ).

Alternatively, the normalized squared error εᵢ described in the second example embodiment may be expressed as an error Lᵢ(θ) by a function with the parameter θ serving as an argument. In the example of FIG. 17, i=1, 2, 3, 4.

In FIG. 17, the current parameter value on the simulation is represented by “0”. Also, in FIG. 17, the parameter values that minimize the errors L₁(θ), L₂(θ), L₃(θ), and L₄(θ) are expressed as “argmine_{θ}L₁(θ)”, “argmine_{θ}L₂(θ)”, “argmine_{θ}L₃(θ)”, and “argmine_{θ}L₄(θ)”, respectively. argmine_{θ}L₂(θ), argmine_{θ}L₃(θ), and argmine_{θ}L₄(θ) are shown at positions close to each other on the parameter value space. It is conceivable that the values of L₂(θ), L₃(θ), and L₄(θ) all become small as the simulator 200 simulates the simulation subject 900 with high accuracy.

On the other hand, argmine_{θ}L₁(θ) is shown at a position away from argmine_{θ}L₂(θ), argmine_{θ}L₃(θ), and argmine_{θ}L₄(θ), as a result of the first sensor of the simulation subject 900 failing. Even if the simulator 200 simulates the simulation subject 900 with high accuracy, it is conceivable that the value of the error L₁(θ) may not become very small due to sensor fault.

The parameter value that minimizes the error Lᵢ(θ) of the output value y\hat{ }ᵢ of the simulator 200 with respect to the output value yᵢ of the simulation subject 900 is also expressed as θ\hat{ }⁽ⁱ⁾.

As shown in Expression (19), the parameter value θ\hat{ }⁽¹⁾ that minimizes the error L₁(θ) of the output value y\hat{ }₁ of the simulator 200 with respect to the output value y₁ of the simulation subject 900 output by a failing sensor differs from the parameter value θ\hat{ }⁽¹⁾ that minimizes the error L₂(θ) of the output value y\hat{ }₂ of the simulator 200 with respect to the output value y₂ of the simulation subject 900 output by a normal sensor.

[Expression 19]

θ\hat{ }⁽¹⁾=argmin_{θ} [symbol] (θ)≠θ\hat{ }⁽²⁾=argmin_{θ} [symbol] ₂(θ) (19)

Also, FIG. 17 shows gradient vectors “∇_{θ}L₁”, “∇_{θ}L₂”, “∇_{θ}L₃”, and “∇_{θ}L₄” of the errors L₁(θ), L₂(θ), L₃(θ), and L₄(θ) in the current parameter values on the simulation. FIG. 17 also shows an average gradient vector “∇_{θ}L”, which is the average of the gradient vectors ∇_{θ}L₁, ∇_{θ}L₂, ∇_{θ}L₃, and ∇_{θ}L₄.

Here, Expression (20) shows the average error L(θ) obtained by averaging the errors L₁(θ), L₂(θ),

$$\begin{matrix}[ Expression 20 ] & \\ ℒ ( θ ) = \frac{1}{N} {\sum }_{k = 1}^{N} {ℒ}_{k} ( θ ) & ( 20 )\end{matrix}$$

N is the number of output items. In the example of FIG. 17, N=4.

The average gradient vector ∇_{θ}L is expressed as Expression (21).

$$\begin{matrix}[ Expression 21 ] & \\ {∇}_{θ} ℒ = \frac{d ℒ ( θ )}{d θ} = \frac{d {ℒ}_{1} ( θ )}{d θ} + \frac{d {ℒ}_{2} ( θ )}{d θ} + \frac{d {ℒ}_{3} ( θ )}{d θ} + ⋯ & ( 21 )\end{matrix}$$

In the example of FIG. 17, the gradient vectors “∇_{θ}L2”, “∇_{θ}L₂”, and “∇_{θ}L4” are similar vectors, as argmine_{θ}L₂(θ), argmine_{θ}L₃(θ), and argmine_{θ}L₄(θ) are positioned close to each other in the parameter value space. That is to say, the difference between the gradient vectors “∇_{θ}L₂”, “∇_{θ}L₃”, and “∇_{θ}L4” is small.

On the other hand, the gradient vector “∇_{θ}L₁” differs from the gradient vectors “∇_{θ}L₂”, “∇_{θ}L₃”, and “∇_{θ}L₄”, as argmin_{θ}L₁(θ) is positioned away from argmine_{θ}L₂(θ), argmine_{θ}L₃(θ), and argmine_{θ}L₄(θ).

The gradient vector “∇_{θ}L₁” being different from the gradient vectors “∇_{θ}L₂”, “∇_{θ}L3”, and “∇_{θ}L₄” can also be expressed as Expression (21) using a differential.

$$\begin{matrix}[ Expression 22 ] & \\ \frac{d {ℒ}_{1} ( θ )}{d θ} \neq \frac{d {ℒ}_{2} ( θ )}{d θ} ≃ \frac{d {ℒ}_{3} ( θ )}{d θ} ≃ ⋯ & ( 22 )\end{matrix}$$

Also, in regard to the average gradient vector ∇_{θ}L, the gradient vectors “∇_{θ}L2”, “∇_{θ}L₃”, and “∇_{θ}L₄” all have a small difference from the average gradient vector ∇_{θ}L.

On the other hand, the gradient vector “∇_{θ}L₁” has a greater difference from the average gradient vector ∇_{θ}L than the gradient vectors “∇_{θ}L₂”, “∇_{θ}L₃”, and “∇_{θ}L_{4”.}

As described above, it is conceivable that the difference between the error gradient vector and the average gradient vector becomes relatively large in the output item with a low normality probability, such as an output item of a failing sensor or an output item with significantly lower accuracy than other sensors.

The difference between the error gradient vector and the average gradient vector can also be expressed as Expression (23).

$$\begin{matrix}[ Expression 23 ] & \\ \frac{d {ℒ}_{i} ( θ )}{d θ} - \frac{1}{N} {\sum }_{k = 1}^{N} \frac{d {ℒ}_{k} ( θ )}{d θ} = \frac{d {ℒ}_{i} ( θ )}{d θ} - \frac{d ℒ ( θ )}{d θ} & ( 23 )\end{matrix}$$

It is conceivable that the larger the difference shown in Expression (23), the lower the normality probability of the sensor.

Accordingly, the weight calculation unit 311 calculates the weight for each output item such that the weight increases as the difference between the gradient vector and the average gradient vector decreases.

For example, the weight calculation unit 311 may calculate the gradient divergence εᵢ of the output value of the simulation subject 900 for each output item using

### Expression (24).

$$\begin{matrix}[ Expression 24 ] & \\ {E}_{i} = {‖ \frac{d {ℒ}_{i} ( θ )}{d θ} - \frac{d ℒ ( θ )}{d θ} ‖}^{2} & ( 24 )\end{matrix}$$

The gradient divergence εᵢ is a degree of difference between the gradient dLᵢ(θ)/de of error Lᵢ(θ) for each output item and the average gradient dL(θ)/dθ of errors for all output items. It is considered that the greater the gradient divergence Eᵢ, the lower the normality probability.

The weight calculation unit 311 may calculate the weight vector w, using Expression (25).

$$\begin{matrix}[ Expression 25 ] & \\ w = {[ 1 - \frac{{E}_{1}}{{Σ}_{k} {E}_{k}} , 1 - \frac{{E}_{2}}{{Σ}_{K} , {E}_{k}} , ⋯ , 1 - \frac{{E}_{N}}{{Σ}_{k} {E}_{k}} ]}^{T} & ( 25 )\end{matrix}$$

“T” represents the transposition of a vector or a matrix. In Expression (25), the weight vector w is indicated by a vertical vector.

However, the weight calculated by the weight calculation unit 311 is not limited to the one shown in Expression (25). The weight calculated by the weight calculation unit 311 can be various weights such that the smaller the difference between the gradient vector and the average gradient vector, the larger the weight.

Regarding “dLᵢ(θ)/dθ” in Expression (24), it is generally considered difficult to explicitly find a function that indicates the behavior of a simulator, and finding a differential of the simulator 200 directly may be difficult in some cases.

Therefore, the gradient vector calculation unit 320 may calculate the gradient vector based on the amount of change in error when the parameter value is randomly changed. For example, the gradient vector calculation unit 320 may randomly change the parameter value so as to differentially approximate the differential dLᵢ(θ)/dθ as shown in Expression (26) multiple times, and estimate the gradient by taking the average of the multiple gradients.

$$\begin{matrix}[ Expression 26 ] & \\ \frac{d {ℒ}_{i} ( θ )}{d θ} ≃ \frac{{ℒ}_{i} ( θ ; x ) - {ℒ}_{i} ( θ + θ ; x )}{Δθ} & ( 26 )\end{matrix}$$

If randomly changing the state of the actual device of the simulation subject 900 is difficult, the behavior of the simulation subject 900 may also be simulated using the simulator 200.

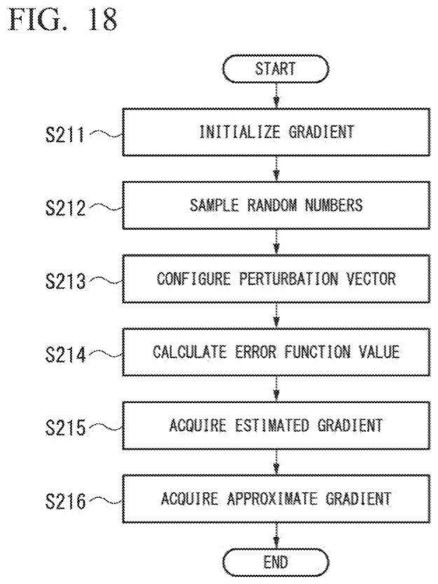

FIG. 18 is a diagram showing an example of a processing procedure for estimating the error differential dLᵢ(θ)/dθ by means of the gradient vector calculation unit 320. The application range of the processing in FIG. 18 may be limited to cases where changes in input or output are small, such as where the simulation subject 900 is in the steady state, for example.

In the processing of FIG. 18, the gradient vector calculation unit 320 initializes the gradient as shown in Expression (27) (Step S211).

[Expression 27]

∇\hat{ }ᵢ [symbol] [0,0, . . . ,0]^{T} (27)

∇\hat{ }θLᵢ represents the estimated value of the gradient of the error Lᵢ. The estimated value of the gradient is also expressed as an estimated gradient.

Next, the gradient vector calculation unit 320 samples a random number for each parameter and sets the variation 40; of the parameter value (Step S212).

For example, the gradient vector calculation unit 320 samples random numbers for the number of parameters from an appropriate distribution such as R=U(−1, 1). If the sample value is 0, sampling is performed again.

Next, the gradient vector calculation unit 320 sets the variation 40; of each parameter value to a sample value to configure the perturbation vector 40 shown in Expression (28) (Step S213).

[Expression 28]

Δθ=[Δθ₁,Δθ₂, . . . ,Δθₚ] (28)

p represents the number of parameters of the simulation model of the simulation subject 900.

For example, if the gradient vector calculation unit 320 samples random numbers from R=U(−1, 1), then each Δθᵢ is set to increase or decrease the parameter value by one.

Next, the gradient vector calculation unit 320 calculates error function values Lᵢ(θ; x) and Lᵢ(θ+Δθ; x) for each of i=1, 2, . . . p B times (Step S214).

B is an integer constant where B≥1.

Next, for each of i=1, 2, . . . p, the gradient vector calculation unit 320 inputs the error function values Lᵢ(θ; x) and Lᵢ(θ+Δθ; x) obtained in Step S214 for each of i=1, 2, . . . p into Expression (29) to update the estimated gradient ∇\hat{ }θLᵢ (Step S215).

$$\begin{matrix}[ Expression 29 ] & \\ {∇}_{θ}^{∧} {ℒ}_{i} ← {∇}_{θ}^{∧} {ℒ}_{i} + {\frac{1}{B} [ \frac{{ℒ}_{i} ( θ ; x ) - {ℒ}_{i} ( θ + Δθ ; x )}{{Δθ}_{1}} , \frac{{ℒ}_{i} ( θ ; x ) - {ℒ}_{i} ( θ + Δθ ; x )}{{Δθ}_{2}} , ⋯ , \frac{{ℒ}_{i} ( θ ; x ) - {ℒ}_{i} ( θ + Δθ ; x )}{{Δθ}_{p}} ]}^{T} & ( 29 )\end{matrix}$$

The gradient vector calculation unit 320 inputs both of the error function values Lᵢ(θ; x) and Lᵢ(θ+Δθ; x) calculated B times in Step S214 into Expression (29) to update the estimated gradient ∇\hat{ }θLᵢ B times.

After having been updated B times, the estimated gradient ∇\hat{ }&L; becomes a gradient obtained by averaging the estimated gradients for B times.

The gradient vector calculation unit 320 adopts the estimated gradient ∇_{θ}Lᵢ having been updated B times as an approximate gradient that approximates the error differential dLᵢ(θ)/dθ.

After Step S215, the gradient vector calculation unit 320 ends the processing of FIG. 18.

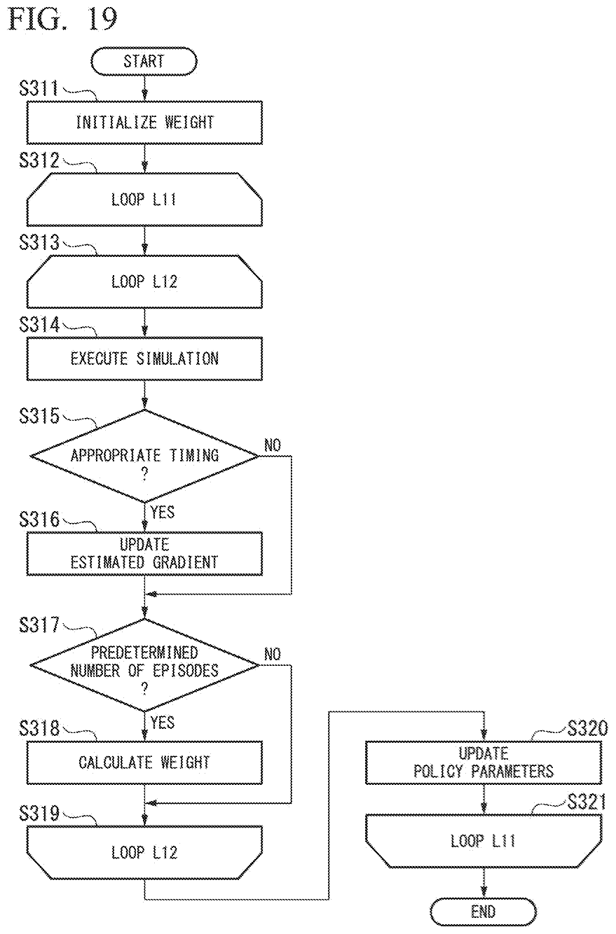

FIG. 19 is a diagram showing an example of a processing procedure for updating error weights performed by the setting device 1θ₂.

In the processing of FIG. 19, a reward function r(y) is defined as shown in Expression (30).

$$\begin{matrix}[ Expression 30 ] & \\ r ( y ) = {\sum }_{k = 1}^{p} {{w}_{k} ( {y}_{k} - {f}_{k}^{∧} ( x ; θ ) )}^{2} & ( 30 )\end{matrix}$$

In the processing of FIG. 19, the weight calculation unit 311 initializes the weight vector w (Step S311). For example, the weight calculation unit 311 sets the initial value of the weight vector w as shown in Expression (31).

$$\begin{matrix}[ Expression 31 ] & \\ w = {[ \frac{1}{N} , \frac{1}{N} , ⋯ , \frac{1}{N} ]}^{T} & ( 31 )\end{matrix}$$

N is a positive integer indicating the number of output items. The weight vector w has N elements, and the sum of all the elements of the weight vector w is one.

Next, the setting device 1θ₂ starts a loop L₁₁ that repeats the processing for the number of times defined as the number of updates of the policy function π (Step S312).

In the processing of the loop L₁₁, the setting device 1θ₂ starts a loop L₁₂ that repeats the processing for the number of episodes defined as the number of episodes used for one update of the policy function π (Step S313). The term episode referred to here is a time series from the start to the end of one simulation of the simulation subject 900 performed by the simulator 200 in learning.

In the processing of the loop L₁₂, the learning control unit 112 causes the simulator 200 to simulate the simulation subject 900, and saves the output value y₁+1 of the simulator 200 shown in Expression (32), and the reward function value obtained by the reward function r(y) in Expression (30) (Step S314).

[Expression 32]

yₜ₊₁=f(x;π(z;α)) (32)

z is a vector representing a control input value, a reference input value, and an output value of the simulator 200. α represents the parameter value of the policy function π.

Moreover, the gradient vector calculation unit 320 determines whether or not the timing condition defined as the estimated gradient update timing is satisfied (Step S315).

If the update timing condition is determined as being satisfied (Step S315: YES), the gradient vector calculation unit 320 updates the estimated value of the gradient dLᵢ(θ)/dθ of the error Lᵢ(θ) (Step S316). For example, the gradient vector calculation unit 320 may perform the processing of FIG. 18 to update the estimated value of the gradient.

Moreover, the weight calculation unit 311 determines whether or not the number of episodes has reached the number of times defined as the weight calculation timing (Step S317).

If the number of episodes is determined as having reached the weight calculation timing (Step S317: YES), the weight calculation unit 311 calculates the weight and reflects the calculated weight in the reward function of Expression (30) (Step S318).

For example, the weight calculation unit 311 may calculate the gradient divergence Eᵢ of the output value of the simulation subject 900 for each output item using Expression (33).

$$\begin{matrix}[ Expression 33 ] & \\ {E}_{i} = {‖ {∇}_{θ}^{∧} {ℒ}_{i} - \frac{1}{p} {\sum }_{k = 1}^{p} {∇}_{θ}^{∧} {ℒ}_{k} ‖}^{2} & ( 33 )\end{matrix}$$

The greater the difference between the error gradient “∇\hat{ }θLᵢ” for each output item and the average error gradient for all output items “1/pΣₖ₌₁^{p}∇\hat{ }_{θ}Lᵢ” is, the greater the value of the gradient divergence εᵢ shown in Expression (33) becomes.

The weight calculation unit 311 may calculate the weight vector w by inputting the gradient divergence εᵢ obtained in Expression (33) into Expression (25).

After Step S318, the learning control unit 112 performs termination processing of the loop L₁₂ (Step S319). Specifically, the learning control unit 112 determines whether or not the processing of the loop L₁₂ has been repeated for a predetermined number of episodes. If the learning control unit 112 determines the processing of the loop L₁₂ as having not been repeated for the predetermined number of episodes, the processing returns to Step S314, and the setting device 1θ₂ continues to repeat the processing of the loop L₁₂.

On the other hand, if the processing of the loop L₁₂ is determined as having been repeated for the predetermined number of episodes, the learning control unit 112 terminates the loop L₁₂.

If the loop L₁₂ ends in Step S319, the learning control unit 112 updates the policy function π by updating the policy parameter α using the saved episode data (Step S320).

After Step S320, the learning control unit 112 performs termination processing of the loop L₁₁ (Step S321). Specifically, the learning control unit 112 determines whether or not the processing of the loop L₁₁ has been repeated for a predetermined number of updates. If the learning control unit 112 determines the processing of the loop Lll as having not been repeated for the predetermined number of updates, the processing returns to Step S313, and the setting device 1θ₂ continues to repeat the processing of the loop L₁₁.

On the other hand, if the processing of the loop L₁₁ is determined as having been repeated for the predetermined number of updates, the learning control unit 112 terminates the loop L₁₁.

If the loop L₁₁ ends in Step S321, the setting device 1θ₂ ends the processing of FIG. 19.

As described above, the gradient vector calculation unit 320 calculates, for each output item of the simulator, a gradient vector indicating the gradient of the error between the output value of the simulator 200 and the reference output value in the parameter value space. The weight calculation unit 311 calculates the weight for each output item such that the weight increases as the difference between the gradient vector and an average gradient vector obtained by averaging the gradient vectors for all the output items decreases.

For an output item where the difference between the gradient vector and the average gradient vector is small, the reference output value is expected to be accurate. According to the setting device 1θ₂, a large weight can be set for an output item for which the reference output value is expected to be accurate, and this is expected to enable effective learning of parameter value settings.

Furthermore, the gradient vector calculation unit 320 calculates the gradient vector based on the amount of change in error when the parameter value is randomly changed.

This allows the setting device 1θ₂ to estimate the gradient of the error even if the error differential cannot be calculated directly.

### Fourth Example Embodiment

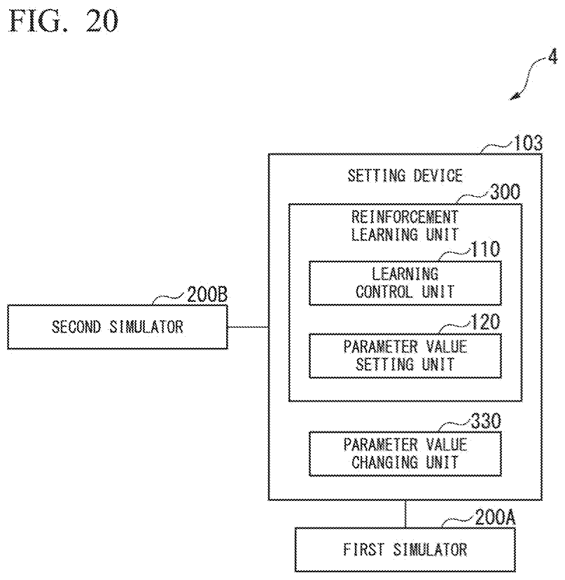

FIG. 20 is a diagram showing a configuration example of a simulation system according to a fourth example embodiment.

With the configuration shown in FIG. 20, a simulation system 4 includes a setting device 103, a first simulator 200A, and a second simulator 200B. The setting device 103 includes a reinforcement learning unit 300, and a parameter value changing unit 330. The reinforcement learning unit 300 includes a learning control unit 110 and a parameter value setting unit 120.

Of the units shown in FIG. 20, ones corresponding to those in FIG. 2 and having the same functions are given the same reference signs (110, 120), and detailed descriptions thereof are omitted.

The simulation system 4 corresponds to an example of the simulation system 1. The setting device 103 corresponds to an example of the setting device 100.

Both the first simulator 200A and the second simulator 200B simulate the simulation subject 900. The first simulator 200A corresponds to an example of the simulator 200 of FIG. 2 and is a subject of parameter value setting performed by the parameter value setting unit 120.

On the other hand, the second simulator 200B is used instead of the simulation subject 900. The output value of the second simulator 200B is used as a reference output value.

The parameter value changing unit 330 changes the parameter value of the second simulator 200B. The parameter value changing unit 330 may change the parameter value of the second simulator 200B while the second simulator 200B executes a simulation.

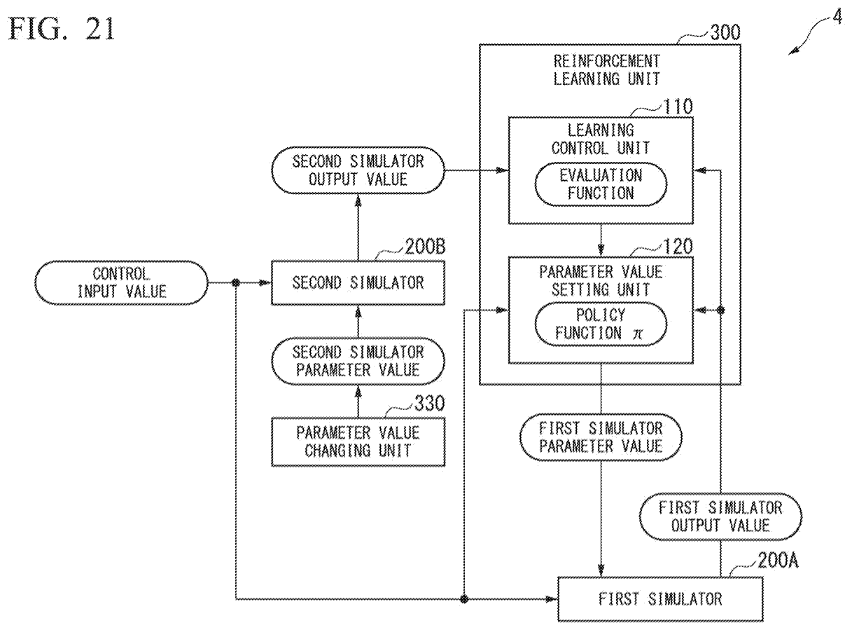

FIG. 21 is a diagram showing an example of data input/output at the time of learning in the simulation system 4. In the example of FIG. 21, the parameter value changing unit 330 sets and changes the parameter value of the second simulator 200B. Upon receiving an input of a control input value, the second simulator 200B executes the simulation of the simulation subject 900 according to the parameter value set and changed by the parameter value changing unit, and calculates an output value. As mentioned above, the output value of the second simulator 200B is used as a reference output value.

The learning control unit 110 receives inputs of the output value of the first simulator 200A and the output value of the second simulator 200B. The learning control unit 110 calculates an evaluation value using an evaluation function in which the smaller the error of the output value of the first simulator 200A with respect to the output value of the second simulator 200B, the higher the evaluation. For example, the learning control unit 110 may calculate the error of the output value of the first simulator 200A with respect to the output value of the second simulator 200B for each output item, and sum the errors for the respective output items.

The learning control unit 110 controls parameter value setting learning performed by the parameter value setting unit 120 so as to increase the evaluation indicated by the evaluation value. Thus, the learning control unit 110 controls learning of parameter value setting performed by the parameter value setting unit 120 so that the output value of the first simulator 200A approximates the output value of the second simulator 200B.

The parameter value setting unit 120 receives inputs of the control input value, the output value of the first simulator 200A, and the output value of the second simulator 200B. The parameter value setting unit 120 inputs each acquired value to the policy function π to calculate the parameter value, and sets the calculated parameter value in the first simulator 200A.

The first simulator 200A executes a simulation of the simulation subject 900 based on the set parameter value, and calculates the output value for the control input value.

As described above, the output value of the second simulator 200B, which simulates the simulation subject 900, is used as a reference output value. The learning control unit 110 uses an evaluation function based on the output value of the first simulator 200A obtained when the same input value as that to the second simulator 200B is entered to the first simulator 200A serving as the simulator for which the parameter value setting device 120 sets the parameter value, and the reference output value, to control learning of parameter value setting of the first simulator performed by the parameter value setting unit 120.

By using the output value of the second simulator 200B as a reference output value in this manner, even when the data obtained from the actual device of the simulation subject 900 is small, the reinforcement learning unit 300 can perform learning of parameter value setting performed by the parameter value setting unit 120.

In addition, by using the output value of the second simulator 200B as a reference output value, the reinforcement learning unit 300 can learn handling of states including an abnormal state that rarely occurs in the actual device of the simulation subject 900.

Moreover, the parameter value changing unit 330 changes the parameter value of the second simulator 200B. The reference output value includes an output value of the second simulator 200B when the parameter value changing unit 330 changes the parameter value of the second simulator 200B.

As described above, as a result of the parameter value changing unit 330 changing the parameter value of the second simulator 200B while a simulation is being executed by the second simulator 200B, a reference output value that handles the dynamically changing state of the simulation subject 900 can be obtained. The reinforcement learning unit 300 learns parameter value setting performed by the parameter value setting unit 120 using this reference output value, so that the parameter value of the first simulator 200A can be set such that the first simulator 200A simulates the simulation subject 900 so as to correspond to the dynamic changes in the state of the simulation subject 900.

Moreover, the parameter value setting unit 120 sets the parameter value of the first simulator 200A that simulates a simulation subject. The learning control unit 110 uses an evaluation function based on the output value of the second simulator 200B that simulates the simulation subject, and the output value of the first simulator 200A obtained when the same input value as that to the second simulator 200B is entered to the first simulator 200A, to control learning of parameter value setting of the first simulator 200A performed by the parameter value setting unit 120.

By using the output value of the second simulator 200B as a reference output value in this manner, even when the data obtained from the actual device of the simulation subject 900 is small, the reinforcement learning unit 300 can perform learning of parameter value setting performed by the parameter value setting unit 120.

In addition, by using the output value of the second simulator 200B as a reference output value, the reinforcement learning unit 300 can learn handling of states including an abnormal state that rarely occurs in the actual device of the simulation subject 900.

The second example embodiment and the fourth example embodiment may be implemented in combination with each other. In such a case, in the configuration of FIG. 20, the reinforcement learning unit 300 may further include the weight calculation unit 310 of FIG. 5, and include the learning control unit 111 of FIG. 5 in place of the learning control unit 110.

The third example embodiment and the fourth example embodiment may be implemented in combination with each other. In such a case, in the configuration of FIG. 20, the reinforcement learning unit 300 may further include the weight calculation unit 320 and the gradient vector calculation unit 320 of FIG. 15, and include the learning control unit 112 of FIG. 15 in place of the learning control unit 110.

### Fifth Example Embodiment

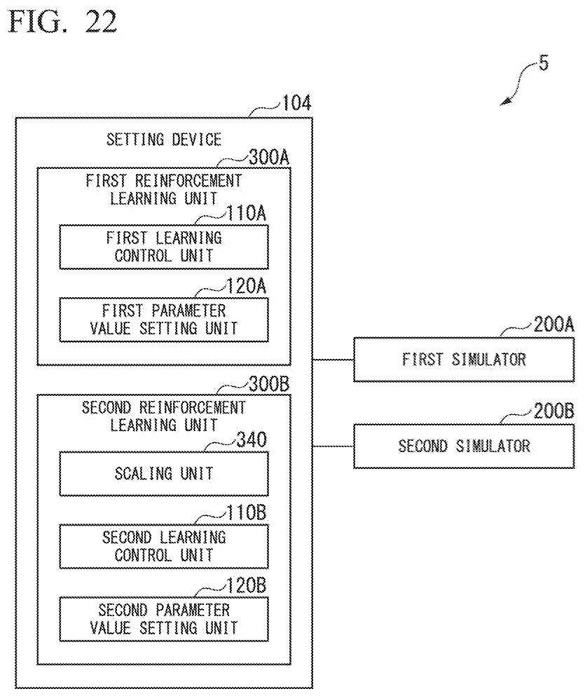

FIG. 22 is a diagram showing a configuration example of a simulation system according to a fifth example embodiment.

With the configuration shown in FIG. 22, a simulation system 5 includes a setting device 104, the first simulator 200A, and the second simulator 200B. The setting device 104 includes a first reinforcement learning unit 300A and a second reinforcement learning unit 300B. The first reinforcement learning unit 300 includes a first learning control unit 110A and a first parameter value setting unit 120A. The second reinforcement learning unit 300B includes a second learning control unit 110B, a second parameter value setting unit 120B, and a scaling unit 340.

The simulation system 5 corresponds to an example of the simulation system 4 of FIG. 20. The setting device 104 corresponds to an example of the setting device 103. The first reinforcement learning unit 300A corresponds to an example of the reinforcement learning unit 300. The first learning control unit 110A corresponds to an example of the learning control unit 110.

The first learning control unit 110A corresponds to an example of the first learning means.

The first parameter value setting unit 120A corresponds to an example of the parameter value setting unit 120. Therefore, the first parameter value setting unit 120A corresponds to an example of the parameter value setting means.

Both the first simulator 200A and the second simulator 200B simulate the simulation subject 900. The first simulator 200A corresponds to an example of the first simulator 200 of FIG. 20 and is a subject of parameter value setting performed by the first parameter value setting unit 120A.

The second simulator 200B corresponds to an example of the second simulator 200B of FIG. 20 and is used in place of the simulation subject 900. The output value of the second simulator 200B is used as a reference output value.

The first parameter value setting unit 120A sets the parameter value of the first simulator 200A so that the output value of the first simulator 200A approximates the output value of the second simulator 200A, through learning performed under the control of the first learning control unit 110A.

The first learning control unit 110A controls parameter value setting learning of the first simulator 200A performed by the first parameter value setting unit 120A so as to reduce the difference between the output value of the first simulator 200A and the output value of the second simulator 200B used as a reference output value.

In contrast, the second parameter value setting unit 120B sets the parameter value of the second simulator 200B so that the output value of the second simulator 200A differs from the output value of the first simulator 200A, through learning performed under the control of the second learning control unit 110B.

The second parameter value setting unit 120B corresponds to an example of the parameter value changing means.

The second learning control unit 110B uses a second evaluation function based on the output value of the first simulator 200A obtained when the same input value as that to the second simulator 200B is entered to the first simulator 200A, and the output value of the second simulator 200B used as a reference output value, to control learning of parameter value setting of the second simulator 200B performed by the second parameter value setting unit 120B, so as to increase the difference between the output value of the first simulator and the reference output value.

The second learning control unit 110B corresponds to an example of the second learning control means.

As a result, the first reinforcement learning unit 300A can perform learning of parameter value setting performed by the first parameter value setting unit 120A, using a control input value that does not allow the first parameter value setting unit 120A to appropriately set the parameter value of the first simulator 200A, and a reference output value. As a result, the first parameter value setting unit 120A is expected to be able to appropriately set the parameter value of the first simulator 200A for various control input values and reference output values.

The scaling unit 340 performs scaling to increase the value of the second evaluation function when learning under the control of the first learning control means progresses beyond a predetermined condition. The predetermined condition referred to here is not limited to a particular upper limit. For example, the predetermined condition may be that learning is performed for a predetermined number of time steps or more; however, it is not limited to this example.

In the initial stage of learning, the scaling unit 340 prioritizes setting of the parameter value of the first simulator 200A performed by the first parameter value setting unit 120A, over setting of the parameter value of the second simulator 200B performed by the second parameter value setting unit 120B.

If the output value of the second simulator 200A is maintained in a state different from that of the output value of the first simulator 200A in the initial stage of learning, learning of first reinforcement learning unit 300A may not progress. Therefore, the scaling unit 340 prioritizes setting of the parameter value of the first simulator 200A performed by the first parameter value setting unit 120A, over setting of the parameter value of the second simulator 200B performed by the second parameter value setting unit 120B. As a result, it is expected that the output value of the first simulator 200A will approximate the output value of the second simulator 200A, and that learning of the first reinforcement learning unit 300A will progress.

The scaling unit 340 corresponds to an example of the scaling means.

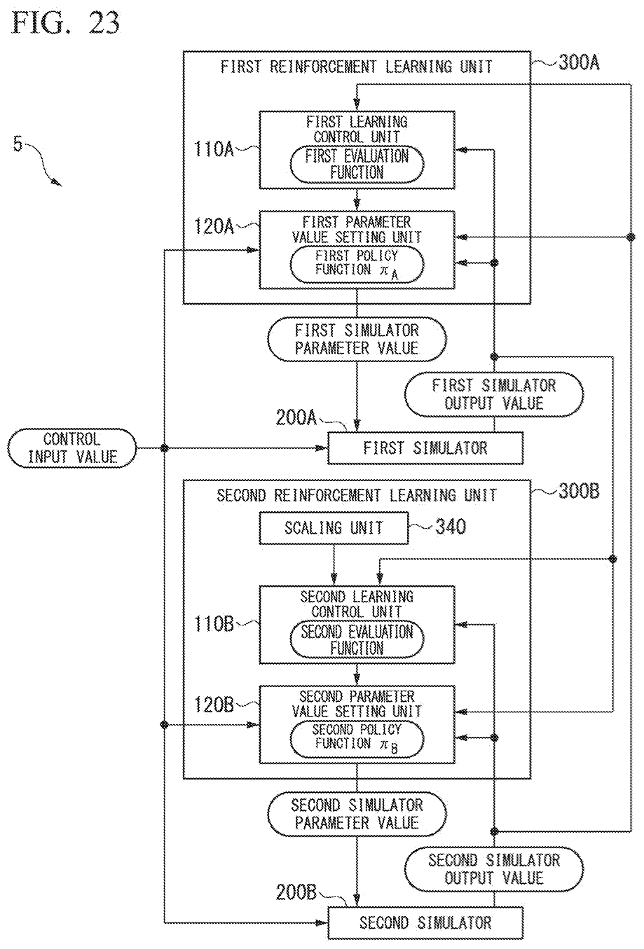

FIG. 23 is a diagram showing an example of data input/output at the time of learning in the simulation system 5.

The first parameter value setting unit 120A receives inputs of a control input value, an output value of the first simulator 200A, and an output value of the second simulator 200B, and inputs these values to a first policy function TA to calculate the parameter value of the first simulator 200A. The first parameter value setting unit 120A sets the calculated parameter value in the first simulator 200A.

The first learning control unit 110A receives inputs of the output value of the first simulator 200A and the output value of the second simulator 200B. The first learning control unit 110A calculates an evaluation value using a first evaluation function in which the smaller the error of the output value of the first simulator 200A with respect to the output value of the second simulator 200B, the higher the evaluation. The first learning control unit 110A controls learning of settings of parameter values of the first simulator 200A by the first parameter value setting unit 120A so as to increase the evaluation indicated by the evaluation value. Thus, the first learning control unit 110A controls learning of parameter value setting performed by the first parameter value setting unit 120A so that the output value of the first simulator 200A approximates the output value of the second simulator 200B.

The first simulator 200A executes a simulation of the simulation subject 900 based on the set parameter value, and calculates the output value for the control input value.

The first parameter value setting unit 120A receives inputs of the control input value, the output value of the first simulator 200A, and the output value of the second simulator 200B, and inputs these values to the first policy function TA to calculate the parameter value of the first simulator 200A. The first parameter value setting unit 120A sets the calculated parameter value in the first simulator 200A.

The second parameter value setting unit 120B receives inputs of a control input value, an output value of the first simulator 200A, and an output value of the second simulator 200B, and inputs these values to a second policy function π_{B} to calculate the parameter value of the second simulator 200B. The second parameter value setting unit 120B sets the calculated parameter value in the second simulator 200B.

The second learning control unit 110B receives inputs of the output value of the first simulator 200A and the output value of the second simulator 200B. The second learning control unit 110B calculates an evaluation value using a second evaluation function in which the greater the error between the output value of the first simulator 200A and the output value of the second simulator 200B, the higher the evaluation. The second learning control unit 110B controls learning of settings of parameter values of the second simulator 200B by the second parameter value setting unit 120B so as to increase the evaluation indicated by the evaluation value. Thus, the second learning control unit 110B controls learning of parameter value setting performed by the second parameter value setting unit 120B so that the output value of the second simulator 200B differs from the output value of the first simulator 200A.

The second simulator 200B executes a simulation of the simulation subject 900 based on the set parameter value, and calculates the output value for the control input value.

The scaling unit 340 performs scaling to increase the value of the second evaluation function when learning under the control of the first learning control means progresses beyond a predetermined condition. As described above, in the initial stage of learning, the scaling unit 340 prioritizes setting of the parameter value of the first simulator 200A performed by the first parameter value setting unit 120A, over setting of the parameter value of the second simulator 200B performed by the second parameter value setting unit 120B.

As described above, the second learning control unit 110B uses the second evaluation function based on the output value of the first simulator 200A obtained when the same input value as that to the second simulator 200B is entered to the first simulator 200A, and the output value of the second simulator 200B used as a reference output value, to control learning of parameter value setting of the second simulator 200B performed by the second parameter value setting unit 120B, so as to increase the difference between the output value of the first simulator 200A and the reference output value.

The first learning control unit 110A controls parameter value setting learning of the first simulator 200A performed by the first parameter value setting unit 120A so as to reduce the difference between the output value of the first simulator 200A and the reference output value.

As a result, the first reinforcement learning unit 300A can perform learning of parameter value setting performed by the first parameter value setting unit 120A, using a control input value that does not allow the first parameter value setting unit 120A to appropriately set the parameter value of the first simulator 200A, and a reference output value. As a result, the first parameter value setting unit 120A is expected to be able to appropriately set the parameter value of the first simulator 200A for various control input values and reference output values.

The scaling unit 340 performs scaling to increase the value of the second evaluation function when learning under the control of the first learning control unit 110A progresses beyond a predetermined condition.

If the output value of the second simulator 200A is maintained in a state different from that of the output value of the first simulator 200A in the initial stage of learning, learning of first reinforcement learning unit 300A may not progress. Therefore, in the initial stage of learning, through the scaling described above, the scaling unit 340 prioritizes setting of the parameter value of the first simulator 200A performed by the first parameter value setting unit 120A, over setting of the parameter value of the second simulator 200B performed by the second parameter value setting unit 120B. As a result, it is expected that the output value of the first simulator 200A will approximate the output value of the second simulator 200A, and that learning of the first reinforcement learning unit 300A will progress.

The second example embodiment and the fifth example embodiment may be implemented in combination with each other. In such a case, in the configuration of FIG. 22, the first reinforcement learning unit 300A may further include the weight calculation unit 310 of FIG. 4, and include the learning control unit 111 of FIG. 4 in place of the first learning control unit 110A.

The third example embodiment and the fifth example embodiment may be implemented in combination with each other. In such a case, in the configuration of FIG. 22, the first reinforcement learning unit 300A may further include the weight calculation unit 311 and the gradient vector calculation unit 320 of FIG. 15, and include the learning control unit 112 of FIG. 15 in place of the first learning control unit 110A.

### Sixth Example Embodiment

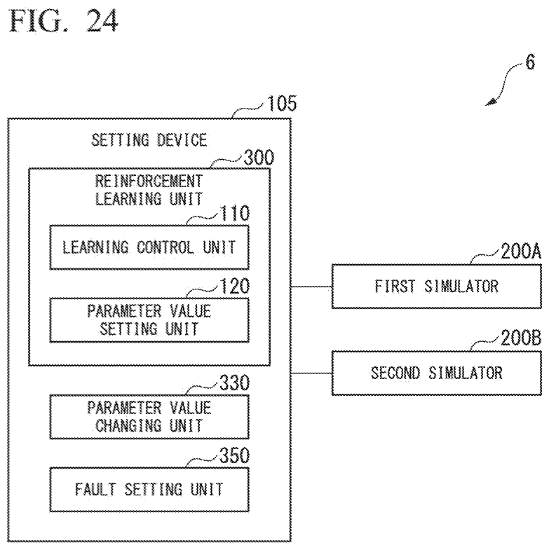

FIG. 24 is a diagram showing a configuration example of a simulation system according to a sixth example embodiment.

With the configuration shown in FIG. 24, a simulation system 6 includes a setting device 105, the first simulator 200A, and the second simulator 200B. The setting device 105 includes the reinforcement learning unit 300, the parameter value changing unit 330, and a fault setting unit 350. The reinforcement learning unit 300 includes the learning control unit 110 and the parameter value setting unit 120.

Of the units shown in FIG. 24, ones corresponding to those in FIG. 20 and having the same functions are given the same reference signs (110, 120, 200A, 200B, 300, 330), and detailed descriptions thereof are omitted.

The simulation system 6 differs from the simulation system 4 in that the setting device 105 further includes the fault setting unit 350 in addition to the respective units of the setting device 103 of FIG. 20.

In other respects, the simulation system 6 is similar to the simulation system 4.

The fault setting unit 350 sets in the second simulator 200B, a fault of a sensor in a simulation model. The fault setting unit 350 may randomly select a sensor for which a fault is to be set. The fault setting unit 305 may switch presence/absence of sensor fault during execution of a simulation performed by the second simulator 200B.

As a result, the reinforcement learning unit 300 allows the parameter value setting unit 120 to perform learning of parameter value setting so that the first simulator 200A simulates the simulation subject 900 with high accuracy even when a sensor of the simulation subject 900 fails.

The fault setting unit 350 corresponds to an example of the fault setting means.

When the fault setting unit 350 sets a sensor fault, the learning control unit 110 may use an evaluation function in which the output value of the sensor for which a fault is set is excluded from the reference subject in the calculation of the evaluation function.

For example, a coefficient may be provided for each output item in the calculation expression of the evaluation function. Then, the learning control unit 110 may set to 0 the coefficient value of the output item corresponding to the sensor for which the fault has been set.

In this manner, it is expected that the reinforcement learning unit 300 can efficiently perform learning as a result of the learning control unit 110 excluding the output value of the sensor for which the fault is set, from the reference target in the calculation of the evaluation function.

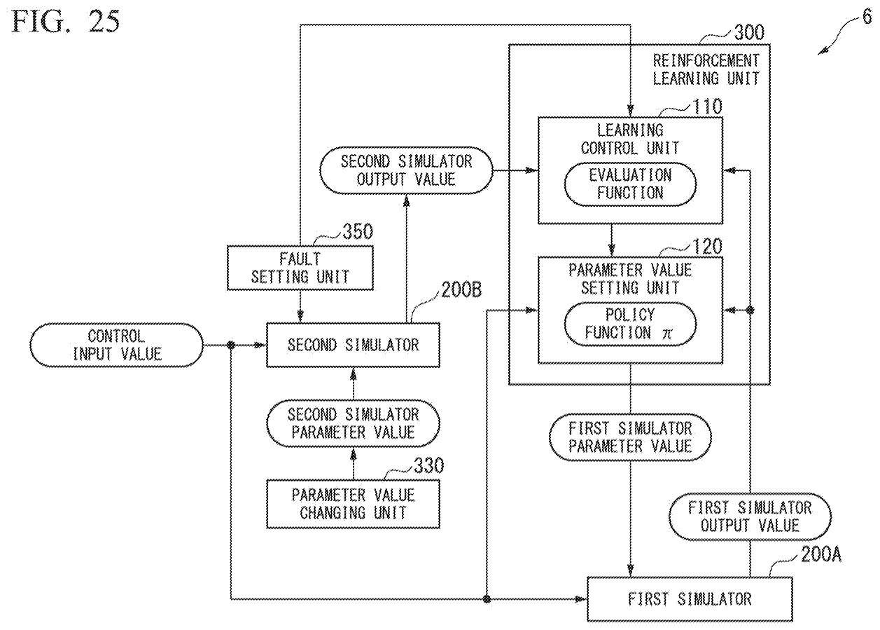

FIG. 25 is a diagram showing an example of data input/output at the time of learning in the simulation system 6. In the example of FIG. 25, the parameter value changing unit 330 sets and changes the parameter value of the second simulator 200B.

The fault setting unit 350 sets in the second simulator 200B, a fault of a sensor in a simulation model.

Upon receiving an input of a control input value, the second simulator 200B executes the simulation of the simulation subject 900 according to the parameter value set and changed by the parameter value changing unit, and the sensor fault set by the fault setting unit 350. As mentioned above, the output value of the second simulator 200B is used as a reference output value.

The learning control unit 110 receives inputs of the output value of the first simulator 200A and the output value of the second simulator 200B. The learning control unit 110 calculates an evaluation value using an evaluation function in which the smaller the error of the output value of the first simulator 200A with respect to the output value of the second simulator 200B, the higher the evaluation. For example, the learning control unit 110 may calculate the error of the output value of the first simulator 200A with respect to the output value of the second simulator 200B for each output item, and sum the errors for the respective output items.

The learning control unit 110 controls parameter value setting learning performed by the parameter value setting unit 120 so as to increase the evaluation indicated by the evaluation value. Thus, the learning control unit 110 controls learning of parameter value setting performed by the parameter value setting unit 120 so that the output value of the first simulator 200A approximates the output value of the second simulator 200B.

The parameter value setting unit 120 receives inputs of the control input value, the output value of the first simulator 200A, and the output value of the second simulator 200B. The parameter value setting unit 120 inputs each acquired value to the policy function π to calculate the parameter value, and sets the calculated parameter value in the first simulator 200A.

The first simulator 200A executes a simulation of the simulation subject 900 based on the set parameter value, and calculates the output value for the control input value.

As described above, the fault setting unit 350 sets in the second simulator 200B, a fault of a sensor in a simulation model.

As a result, the reinforcement learning unit 300 allows the parameter value setting unit 120 to perform learning of parameter value setting so that the first simulator 200A simulates the simulation subject 900 with high accuracy even when a sensor of the simulation subject 900 fails.

Moreover, the learning control unit 110 uses an evaluation function in which the output value of the sensor for which a fault is set is excluded from the reference subject in the calculation of the evaluation function.

In this manner, it is expected that the reinforcement learning unit 300 can efficiently perform learning as a result of the learning control unit 110 excluding the output value of the sensor for which the fault is set, from the reference target in the calculation of the evaluation function.

The second example embodiment and the sixth example embodiment may be implemented in combination with each other. In such a case, the setting device 101 may further include the fault setting unit 350 in the configuration of FIG. 4.

The third example embodiment and the sixth example embodiment may be implemented in combination with each other. In such a case, the setting device 1θ₂ may further include the fault setting unit 350 in the configuration of FIG. 15.

The fifth example embodiment and the sixth example embodiment may be implemented in combination with each other. In such a case, the setting device 104 may further include the fault setting unit 350 in the configuration of FIG. 22.

Furthermore, the second example embodiment, the fifth example embodiment, and the sixth example embodiment may be implemented in combination with each other. The third example embodiment, the fifth example embodiment and the sixth example embodiment may be implemented in combination with each other.

In any one of the first to sixth example embodiments, or a combination thereof, the learning control means may use an evaluation function based on the output value of the simulator at a time in the simulation of the simulation subject performed by the simulator, which includes the time in the future after the time at which the parameter value setting means sets the parameter value.

As a result, it is expected that the parameter value setting means sets the parameter value of the simulator such that the simulator simulates the control subject with high accuracy in the future time.

In the first example embodiment, the learning control unit 110 corresponds to an example of the learning control means here. The simulator 200 corresponds to an example of the simulator here. The parameter value setting unit 120 corresponds to an example of the parameter value setting means here.

In the second example embodiment, the learning control unit 111 corresponds to an example of the learning control means here. The simulator 200 corresponds to an example of the simulator here. The parameter value setting unit 120 corresponds to an example of the parameter value setting means here.

In the third example embodiment, the learning control unit 112 corresponds to an example of the learning control means here. The simulator 200 corresponds to an example of the simulator here. The parameter value setting unit 120 corresponds to an example of the parameter value setting means here.

In the fourth example embodiment, the learning control unit 110 corresponds to an example of the learning control means here. The first simulator 200A corresponds to an example of the simulator here. The parameter value setting unit 120 corresponds to an example of the parameter value setting means here.

In the fifth example embodiment, the first learning control unit 110A corresponds to an example of the learning control means here. The first simulator 200A corresponds to an example of the simulator here. The first parameter value setting unit 120A corresponds to an example of the parameter value setting means here.

In the sixth example embodiment, the learning control unit 110 corresponds to an example of the learning control means here. The first simulator 200A corresponds to an example of the simulator here. The parameter value setting unit 120 corresponds to an example of the parameter value setting means here.

### Seventh Example Embodiment

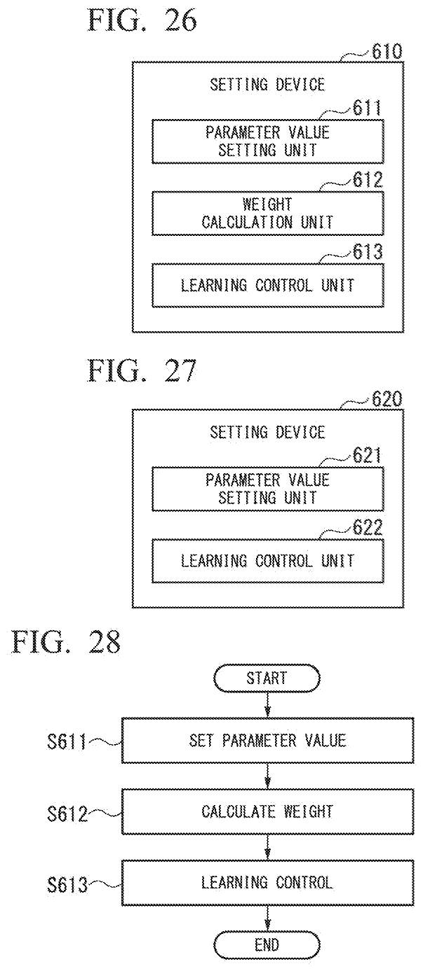

FIG. 26 is a diagram showing a configuration example of a setting device according to a seventh example embodiment.

In the configuration shown in FIG. 26, a setting device 610 includes a parameter value setting unit 611, a weight calculation unit 611, and a learning control unit 613.

The parameter value setting unit 611 sets a parameter value of a simulator that simulates a simulation subject. The weight calculation unit 612 calculates the weight of each output item on the basis of the output value of the simulator, and the reference output value that is subject to simulation based on the output value of the simulator. The learning control unit 613 controls learning of simulator parameter value setting performed by the parameter value setting unit 611, using an evaluation function based on the output value of the simulator, the reference output value, and the weight.

The parameter value setting unit 611 corresponds to an example of the parameter value setting means. The weight calculation unit 612 corresponds to an example of the weight calculation means. The learning control unit 613 corresponds to an example of the learning control means.

According to the setting device 610, it is possible to set the weight small to reduce the influence thereof on the evaluation value for an output item whose normality probability of the reference output value is low due to a sensor fault or the like. According to the setting device 610, in this respect, it is expected that learning of simulator parameter value setting can be performed effectively when the output values of a plurality of items can be obtained from a simulation subject.

The parameter value setting unit 611 can be implemented using the function of the parameter value setting unit 120 shown in FIG. 4, for example. The weight calculation unit 612 can be implemented using the function of the weight calculation unit 310 shown in FIG. 4, for example. The learning control unit 613 can be implemented using the function of the learning control unit 111 shown in FIG. 4, for example.

### Eighth Example Embodiment

FIG. 27 is a diagram showing a configuration example of a setting device according to an eighth example embodiment.

In the configuration shown in FIG. 27, a setting device 620 includes a parameter value setting unit 621, and a learning control unit 622.

The parameter value setting unit 621 sets a parameter value of a first simulator that simulates a simulation subject. The learning control unit 622 uses an evaluation function based on the output value of the second simulator that simulates the simulation subject, and the output value of the first simulator obtained when the same input value as that to the second simulator is entered to the first simulator, to control learning of parameter value setting of the first simulator performed by the parameter value setting unit 621.

The parameter value setting unit 621 corresponds to an example of the parameter value setting means. The learning control unit 622 corresponds to an example of the learning control means.

According to the setting device 620, by performing learning using the output value of the second simulator, it is possible to learn parameter value setting performed by the parameter value setting unit 621 even when the data obtained from the actual device to be simulated is small.

Moreover, according to the setting device 620, by performing learning using the output value of the second simulator, it is possible to learn handling of states including an abnormal state that rarely occurs in the actual device of the simulation subject.

The parameter value setting unit 621 can be implemented using the function of the parameter value setting unit 120 shown in FIG. 20, for example. The learning control unit 622 can be implemented using the function of the learning control unit 110 shown in FIG. 20, for example.

### Ninth Example Embodiment

FIG. 28 is a diagram showing an example of a processing procedure in a setting method according to a ninth example embodiment.

The setting method shown in FIG. 28 includes setting a parameter value (Step S611), calculating a weight (Step S612), and controlling learning (Step S613).

In setting a parameter value (Step S611), a parameter value of a simulator that simulates a simulation subject is set. In calculating a weight (Step S612), the weight of each output item is calculated on the basis of the output value of the simulator, and the reference output value that is subject to simulation based on the output value of the simulator. In controlling learning (Step S613), learning of simulator parameter value setting is performed, using an evaluation function based on the output value of the simulator, the reference output value, and the weight.

According to the setting method shown in FIG. 28, it is possible to set the weight small to reduce the influence thereof on the evaluation value for an output item whose normality probability of the reference output value is low due to a sensor fault or the like. According to the setting method shown in FIG. 28, in this respect, it is expected that learning of simulator parameter value setting can be performed effectively when the output values of a plurality of items can be obtained from a simulation subject.

### Tenth Example Embodiment

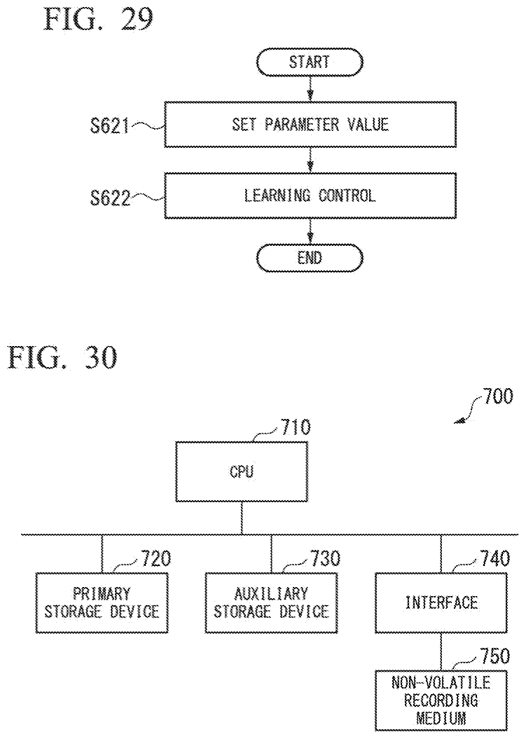

FIG. 29 is a diagram showing an example of a processing procedure in a setting method according to a tenth example embodiment.

The setting method shown in FIG. 29 includes setting a parameter value (Step S621), and controlling learning (Step S622).

In setting a parameter value (Step S621), a parameter value of a first simulator that simulates a simulation subject is set. In controlling learning (Step S622), an evaluation function based on the output value of the second simulator that simulates the simulation subject, and the output value of the first simulator obtained when the same input value as that to the second simulator is entered to the first simulator, is used to control learning of the setting of the parameter value of the first simulator.

According to the setting method shown in FIG. 29, by performing learning using the output value of the second simulator, it is possible to learn parameter value setting even when the data obtained from the actual device to be simulated is small.

Furthermore, according to the setting method shown in FIG. 29, by performing learning using the output value of the second simulator, it is possible to learn handling of states including an abnormal state that rarely occurs in the actual device of the simulation subject.

FIG. 30 is a schematic block diagram showing a configuration of a computer according to at least one example embodiments.

In the configuration shown in FIG. 30, a computer 700 includes a CPU 710, a primary storage device 720, an auxiliary storage device 730, an interface 740, and a non-volatile recording medium 750.

One or more of the setting devices 100, 101, 102, 103, 104, 105, 610, 620 or part thereof may be implemented in the computer 700. In such a case, operations of the respective processing units described above are stored in the auxiliary storage device 730 in the form of a program. The CPU 710 reads out the program from the auxiliary storage device 730, loads it on the primary storage device 720, and executes the processing described above according to the program. Moreover, the CPU 710 reserves, according to the program, storage regions corresponding to the respective storage units mentioned above, in the primary storage device 720. Communication between each device and other devices is executed by the interface 740 having a communication function and communicating under the control of the CPU 710. The interface 740 also has a port for the non-volatile recording medium 750, and reads information from the non-volatile recording medium 750 and writes information to the non-volatile recording medium 750.

In the case where the setting device 100 is implemented in the computer 700, operations of the learning control unit 110 and the parameter value setting unit 120 are stored in the form of a program in the auxiliary storage device 730. The CPU 710 reads out the program from the auxiliary storage device 730, loads it on the primary storage device 720, and executes the processes described above, according to the program.

Also, the CPU 710 reserves a storage region in the primary storage device 720 for the processing to be performed by the setting device 100 according to the program.

Communication with another device performed by the setting device 100 is executed by the interface 740 having a communication function, and operating under the control of the CPU 710.

Interaction between the setting device 100 and a user is executed by the interface 740 having an input device and an output device, presenting information to the user through the output device under the control of the CPU 710, and receiving user operations through the input device.

In the case where the setting device 101 is implemented in the computer 700, operations of the learning control unit 111, the parameter value setting unit 120, and the weight calculation unit 310 are stored in the form of a program in the auxiliary storage device 730. The CPU 710 reads out the program from the auxiliary storage device 730, loads it on the primary storage device 720, and executes the processes described above, according to the program.

Also, the CPU 710 reserves a storage region in the primary storage device 720 for the processing to be performed by the setting device 101 according to the program.

Communication with another device performed by the setting device 101 is executed by the interface 740 having a communication function, and operating under the control of the CPU 710.

Interaction between the setting device 101 and a user is executed by the interface 740 having an input device and an output device, presenting information to the user through the output device under the control of the CPU 710, and receiving user operations through the input device.

In the case where the setting device 1θ₂ is implemented in the computer 700, operations of the learning control unit 112, the parameter value setting unit 120, the weight calculation unit 311, and the gradient vector calculation unit 320 are stored in the form of a program in the auxiliary storage device 730. The CPU 710 reads out the program from the auxiliary storage device 730, loads it on the primary storage device 720, and executes the processes described above, according to the program.

Also, the CPU 710 reserves a storage region in the primary storage device 720 for the processing to be performed by the setting device 1θ₂ according to the program.

Communication with another device performed by the setting device 1θ₂ is executed by the interface 740 having a communication function, and operating under the control of the CPU 710.

Interaction between the setting device 1θ₂ and a user is executed by the interface 740 having an input device and an output device, presenting information to the user through the output device under the control of the CPU 710, and receiving user operations through the input device.

In the case where the setting device 103 is implemented in the computer 700, operations of the reinforcement learning unit 300, the parameter value changing unit 330, and units thereof are stored in the form of a program in the auxiliary storage device 730. The CPU 710 reads out the program from the auxiliary storage device 730, loads it on the primary storage device 720, and executes the processes described above, according to the program.

Also, the CPU 710 reserves a storage region in the primary storage device 720 for the processing to be performed by the setting device 103 according to the program.

Communication with another device performed by the setting device 103 is executed by the interface 740 having a communication function, and operating under the control of the CPU 710.

Interaction between the setting device 103 and a user is executed by the interface 740 having an input device and an output device, presenting information to the user through the output device under the control of the CPU 710, and receiving user operations through the input device.

In the case where the setting device 104 is implemented in the computer 700, operations of the first reinforcement learning unit 300A, the second reinforcement learning unit 300B, and units thereof are stored in the form of a program in the auxiliary storage device 730. The CPU 710 reads out the program from the auxiliary storage device 730, loads it on the primary storage device 720, and executes the processes described above, according to the program.

Also, the CPU 710 reserves a storage region in the primary storage device 720 for the processing to be performed by the setting device 104 according to the program.

Communication with another device performed by the setting device 104 is executed by the interface 740 having a communication function, and operating under the control of the CPU 710.

Interaction between the setting device 104 and a user is executed by the interface 740 having an input device and an output device, presenting information to the user through the output device under the control of the CPU 710, and receiving user operations through the input device.

In the case where the setting device 105 is implemented in the computer 700, operations of the reinforcement learning unit 300, the parameter value changing unit 330, the fault setting unit 350, and units thereof are stored in the form of a program in the auxiliary storage device 730. The CPU 710 reads out the program from the auxiliary storage device 730, loads it on the primary storage device 720, and executes the processes described above, according to the program.

Also, the CPU 710 reserves a storage region in the primary storage device 720 for the processing to be performed by the setting device 105 according to the program.

Communication with another device performed by the setting device 105 is executed by the interface 740 having a communication function, and operating under the control of the CPU 710.

Interaction between the setting device 105 and a user is executed by the interface 740 having an input device and an output device, presenting information to the user through the output device under the control of the CPU 710, and receiving user operations through the input device.

In the case where the setting device 610 is implemented in the computer 700, operations of the parameter value setting unit 112, the weight calculation unit 612, and the learning control unit 613 are stored in the form of a program in the auxiliary storage device 730. The CPU 710 reads out the program from the auxiliary storage device 730, loads it on the primary storage device 720, and executes the processes described above, according to the program.

Also, the CPU 710 reserves a storage region in the primary storage device 720 for the processing to be performed by the setting device 610 according to the program.

Communication with another device performed by the setting device 610 is executed by the interface 740 having a communication function, and operating under the control of the CPU 710.

Interaction between the setting device 610 and a user is executed by the interface 740 having an input device and an output device, presenting information to the user through the output device under the control of the CPU 710, and receiving user operations through the input device.

In the case where the setting device 620 is implemented in the computer 700, operations of the parameter value setting unit 112 and the learning control unit 622 are stored in the form of a program in the auxiliary storage device 730. The CPU 710 reads out the program from the auxiliary storage device 730, loads it on the primary storage device 720, and executes the processes described above, according to the program.

Also, the CPU 710 reserves a storage region in the primary storage device 720 for the processing to be performed by the setting device 620 according to the program.

Communication with another device performed by the setting device 620 is executed by the interface 740 having a communication function, and operating under the control of the CPU 710.

Interaction between the setting device 620 and a user is executed by the interface 740 having an input device and an output device, presenting information to the user through the output device under the control of the CPU 710, and receiving user operations through the input device.

Any one or more of the programs described above may be recorded in the non-volatile recording medium 750. In such a case, the interface 740 may read the program from the non-volatile recording medium 750. Then, the CPU 710 directly executes the program read by the interface 740, or it may be temporarily stored in the primary storage device 720 or the auxiliary storage device 730 and then executed.

It should be noted that a program for executing some or all of the processes performed by the setting devices 100, 101, 102, 103, 104, 105, 610, 620 may be recorded on a computer-readable recording medium, and the program recorded on the recording medium may be read into and executed on a computer system, to thereby perform the processing of each unit. The “computer system” referred to here includes an OS and hardware such as peripheral devices.

Moreover, the “computer-readable recording medium” referred to here refers to a portable medium such as a flexible disk, a magnetic optical disk, a ROM (Read Only Memory), and a CD-ROM (Compact Disc Read Only Memory), or a storage device such as a hard disk built in a computer system. The above program may be a program for realizing a part of the functions described above, and may be a program capable of realizing the functions described above in combination with a program already recorded in a computer system.

The example embodiments of the present invention have been described in detail with reference to the drawings. However, the specific configuration of the invention is not limited to the example embodiments, and may include designs and so forth that do not depart from the scope of the present invention.

The whole or part of the example embodiments disclosed above can be described as, but not limited to, the following supplementary notes.

### Supplementary Note 1

A setting device comprising:
a parameter value setting means that sets a parameter value of a simulator that simulates a simulation subject;
a weight calculation means that calculates weights of respective output items based on an output value of the simulator and a reference output value, the reference output value being subject to simulation according to the output value of the simulator; and
a learning control means that controls, by using an evaluation function, learning of a setting of a parameter value of the simulator by the parameter value setting means, the evaluation function being based on the output value of the simulator, the reference output value, and the weights.

### Supplementary Note 2

The setting device according to supplementary note 1, wherein the weight calculation means calculates the weights of the respective output items such that the output item having a larger normalized error obtained by normalizing errors of the respective output items has a smaller weight.

### Supplementary Note 3

The setting device according to supplementary note 2, wherein the learning control means calculates, for each unit of the learning, an error index value indicating magnitude of a weighted error between the output value of the simulator and the reference output value for the entire output items, and when the error index value after executing one unit of learning indicates that an error is larger than the error index value before executing the one unit of learning, sets the weight back to the weight before executing the one unit of learning.

### Supplementary Note 4

The setting device according to supplementary note 1, further comprising: a gradient vector calculation means that calculates, for each output item of the simulator, a gradient vector indicating the gradient of the error between the simulator output value and the reference output value in the parameter value space, wherein the weight calculation means calculates the weights for the respective output items such that the weight increases as a difference between the gradient vector and an average gradient vector decreases, the average gradient vector being obtained by averaging the gradient vectors for all the output items.

### Supplementary Note 5

The setting device according to supplementary note 4, wherein the gradient vector calculation means calculates the gradient vector based on an amount of change in the error when the parameter value is randomly changed.

### Supplementary Note 6

The setting device according to any one of supplementary notes 1 to 5, wherein the learning control means uses the evaluation function based on the output value of the simulator at a time in simulation of the simulation subject performed by the simulator, the time including a time in future after time at which the parameter value setting means sets the parameter value.

### Supplementary Note 7

The setting device according to any one of supplementary notes 1 to 6,
wherein the reference output value is an output value of a second simulator that simulates the simulation target, and
the learning control means controls learning of the setting of the parameter value of the simulator by the parameter value setting means, by using an evaluation function based on an output value of a first simulator obtained when an input value that is same as an input value to the second simulator is entered to the first simulator, the reference output value, and the weights, the first simulator being the simulator for which the parameter value setting means sets the parameter value.

### Supplementary Note 8

The setting device according to supplementary note 7, further comprising:
a parameter value changing means that changes a parameter value of the second simulator,
wherein the reference output value includes an output value of the second simulator when the parameter value changing means changes the parameter value of the second simulator.

### Supplementary Note 9

The setting device according to supplementary note 8, further comprising:
a second learning control means control, by using a second evaluation function, learning of a setting of the parameter value of the second simulator by the parameter value setting means so as to increase a difference between the output value of the first simulator and the reference output value, the second evaluation function being based on an output value of the first simulator obtained when an input value that is same as an input value to the second simulator is entered to the first simulator, and the reference output value,
wherein the learning control means that controls the learning of the parameter value of the first simulator is a first learning control means that controls the learning of the setting of the parameter value of the first simulator by the parameter value setting means so as to reduce a difference between the output value of the first simulator and the reference output value.

### Supplementary Note 10

The setting device according to supplementary note 9, further comprising:
a scaling means that performs scaling to increase a value of the second evaluation function when the learning under control of the first learning control means progresses beyond a predetermined condition.

### Supplementary Note 11

The setting device according to any one of supplementary notes 8 to 10, further comprising:

a fault setting means that sets, to the second simulator, a sensor fault in a simulation model.

### Supplementary Note 12

The setting device according to supplementary note 11, wherein the weight calculation means sets the weight for an output value of the sensor for which a fault is set, to a value indicating exclusion from a calculation subject of the evaluation function.

### Supplementary Note 13

A setting device comprising:
a parameter value setting means that sets a parameter value of a first simulator that simulates a simulation subject; and
a learning control means that controls, by using an evaluation function, learning of a setting of the parameter value of the first simulator by the parameter value setting means, the evaluation function being based on an output value of a second simulator that simulates the simulation subject, and an output value of the first simulator obtained when an input value that is same as an input value to the second simulator is entered to the first simulator.

### Supplementary Note 14

The setting device according to supplementary note 13, further comprising:

a parameter value changing means that changes a parameter value of the second simulator,
wherein the output value of the second simulator includes an output value when the parameter value changing means changes the parameter value of the second simulator.

### Supplementary Note 15

The setting device according to supplementary note 14, further comprising:
a second learning control means that controls, by using a second evaluation function, learning of a setting of the parameter value of the second simulator by the parameter value setting means so as to increase a difference between the output value of the first simulator and the output value of the second simulator, the second evaluation function being based on an output value of the first simulator obtained when an input value that is same as an input value to the second simulator is entered to the first simulator, and the output value of the second simulator,
wherein the learning control means that controls the learning of the parameter value of the first simulator is a first learning control means that controls the learning of the setting of the parameter value of the first simulator by the parameter value setting means so as to reduce a difference between the output value of the first simulator and the output value of the second simulator.

### Supplementary Note 16

The setting device according to supplementary note 15, further comprising:
a scaling means that performs scaling to increase a value of the second evaluation function when the learning under control of the first learning control means progresses beyond a predetermined condition.

### Supplementary Note 17

The setting device according to any one of supplementary notes 14 to 16, further comprising:
a fault setting means that sets, to the second simulator, a sensor fault in a simulation model.

### Supplementary Note 18

The setting device according to supplementary note 17, wherein the learning control means uses the evaluation function in which an output value of the sensor for which fault setting is performed is excluded from a reference subject in calculation of the evaluation function.

### Supplementary Note 19

A setting method executed by a computer, comprising:
setting a parameter value of a simulator that simulates a simulation subject;
calculating weights of respective output items based on an output value of the simulator and a reference output value, the reference output value being subject to simulation according to the output value of the simulator; and
controlling, by using an evaluation function, learning of a setting of a parameter value of the simulator, the evaluation function being based on the output value of the simulator, the reference output value, and the weights.

### Supplementary Note 20

A setting method executed by a computer, comprising:
setting a parameter value of a first simulator that simulates a simulation subject; and
controlling, by using an evaluation function, learning of a setting of the parameter value of the first simulator, the evaluation function being based on an output value of a second simulator that simulates the simulation subject, and an output value of the first simulator obtained when an input value that is same as an input value to the second simulator is entered to the first simulator.

### Supplementary Note 21

A recording medium having recorded therein a program causing a computer to execute:
setting a parameter value of a simulator that simulates a simulation subject;
calculating weights of respective output items based on an output value of the simulator and a reference output value, the reference output value being subject to simulation according to the output value of the simulator; and
controlling, by using an evaluation function, learning of a setting of a parameter value of the simulator, the evaluation function being based on the output value of the simulator, the reference output value, and the weights.

### Supplementary Note 22

A recording medium having recorded therein a program causing a computer to execute:
setting a parameter value of a first simulator that simulates a simulation subject; and
controlling, by using an evaluation function, learning of a setting of the parameter value of the first simulator, the evaluation function being based on an output value of a second simulator that simulates the simulation subject, and an output value of the first simulator obtained when an input value that is same as an input value to the second simulator is entered to the first simulator.

### INDUSTRIAL APPLICABILITY

The example embodiments of the present invention may be applied to a setting device, a setting method, and a recording medium.

### DESCRIPTION OF REFERENCE SYMBOLS

1, 2, 3, 4, 5, 6 Simulation system
100, 101, 102, 103, 104, 105, 610, 620 Setting device
110, 111, 112, 613, 622 Learning control unit
110A First learning control unit
110B Second learning control unit
120, 611, 621 Parameter value setting unit
120A First parameter value setting unit
120B Second parameter value setting unit
130 Weight setting unit
200 Simulator
200A First simulator
200B Second simulator
300 Reinforcement learning unit
300A First reinforcement learning unit
300B Second reinforcement learning unit
310, 311, 612 Weight calculation unit
320 Gradient vector calculation unit
330 Parameter value changing unit
340 Scaling unit
350 Fault setting unit
900 Simulation subject

What is claimed is:

1. A setting device comprising:
a memory configured to store instructions; and
a processor configured to execute the instructions to:
set a parameter value of a simulator that simulates a simulation subject;
calculate weights of respective output items based on an output value of the simulator and a reference output value, the reference output value being subject to simulation according to the output value of the simulator; and
control, by using an evaluation function, learning of a setting of a parameter value of the simulator, the evaluation function being based on the output value of the simulator, the reference output value, and the weights.

2. The setting device according to claim 1, wherein the processor is configured to execute the instructions to calculate the weights of the respective output items such that the output item having a larger normalized error obtained by normalizing errors of the respective output items has a smaller weight.

3. The setting device according to claim 2, wherein the processor is configured to execute the instructions to calculate, for each unit of the learning, an error index value indicating magnitude of a weighted error between the output value of the simulator and the reference output value for the entire output items, and when the error index value after executing one unit of learning indicates that an error is larger than the error index value before executing the one unit of learning, set the weight back to the weight before executing the one unit of learning.

4. The setting device according to claim 1,
wherein the processor is configured to execute the instructions to calculate, for each output item of the simulator, a gradient vector indicating the gradient of the error between the simulator output value and the reference output value in the parameter value space, and
wherein the processor is configured to execute the instructions to calculate the weights for the respective output items such that the weight increases as a difference between the gradient vector and an average gradient vector decreases, the average gradient vector being obtained by averaging the gradient vectors for all the output items.

5. The setting device according to claim 4, wherein the processor is configured to execute the instructions to calculate the gradient vector based on an amount of change in the error when the parameter value is randomly changed.

6. The setting device according to claim 1, wherein the processor is configured to execute the instructions to use the evaluation function based on the output value of the simulator at a time in simulation of the simulation subject performed by the simulator, the time including a time in future after time at which the parameter value is set.

7. The setting device according to, claim 1,
wherein the reference output value is an output value of a second simulator that simulates the simulation target, and
the processor is configured to execute the instructions to control learning of the setting of the parameter value of the simulator, by using an evaluation function based on an output value of a first simulator obtained when an input value that is same as an input value to the second simulator is entered to the first simulator, the reference output value, and the weights, the first simulator being the simulator for which the parameter value setting means sets the parameter value.

8. The setting device according to claim 7,
wherein the processor is configured to execute the instructions to change a parameter value of the second simulator, and
wherein the reference output value includes an output value of the second simulator when the parameter value of the second simulator is changed.

9. The setting device according to claim 8,
wherein the processor is configured to execute the instructions to control, by using a second evaluation function, learning of a setting of the parameter value of the second simulator so as to increase a difference between the output value of the first simulator and the reference output value, the second evaluation function being based on an output value of the first simulator obtained when an input value that is same as an input value to the second simulator is entered to the first simulator, and the reference output value, and
wherein the processor is configured to execute the instructions to control the learning of the setting of the parameter value of the first simulator so as to reduce a difference between the output value of the first simulator and the reference output value.

10. The setting device according to claim 9,
wherein the processor is configured to execute the instructions to perform scaling to increase a value of the second evaluation function when the learning progresses beyond a predetermined condition.

11. The setting device according to claim 8,
wherein the processor is configured to execute the instructions to set, to the second simulator, a sensor fault in a simulation model.

12. The setting device according to claim 11, wherein the processor is configured to execute the instructions to set the weight for an output value of the sensor for which a fault is set, to a value indicating exclusion from a calculation subject of the evaluation function.

13. A setting device comprising:
a memory configured to store instructions; and
a processor configured to execute the instructions to:
set a parameter value of a first simulator that simulates a simulation subject; and
control, by using an evaluation function, learning of a setting of the parameter value of the first simulator, the evaluation function being based on an output value of a second simulator that simulates the simulation subject, and an output value of the first simulator obtained when an input value that is same as an input value to the second simulator is entered to the first simulator.

14. The setting device according to claim 13,
wherein the processor is configured to execute the instructions to change a parameter value of the second simulator, and
wherein the output value of the second simulator includes an output value when the parameter value of the second simulator is changed.

15. The setting device according to claim 14,
wherein the processor is configured to execute the instructions to control, by using a second evaluation function, learning of a setting of the parameter value of the second simulator so as to increase a difference between the output value of the first simulator and the output value of the second simulator, the second evaluation function being based on an output value of the first simulator obtained when an input value that is same as an input value to the second simulator is entered to the first simulator, and the output value of the second simulator,
wherein the processor is configured to execute the instructions to control the learning of the setting of the parameter value of the first simulator so as to reduce a difference between the output value of the first simulator and the output value of the second simulator.

16. The setting device according to claim 15,
wherein the processor is configured to execute the instructions to perform scaling to increase a value of the second evaluation function when the learning progresses beyond a predetermined condition.

17. The setting device according to
claim 14,
wherein the processor is configured to execute the instructions to set, to the second simulator, a sensor fault in a simulation model.

18. The setting device according to claim 17, wherein the processor is configured to execute the instructions to use the evaluation function in which an output value of the sensor for which fault setting is performed is excluded from a reference subject in calculation of the evaluation function.

19. A setting method executed by a computer, comprising:
setting a parameter value of a simulator that simulates a simulation subject;
calculating weights of respective output items based on an output value of the simulator and a reference output value, the reference output value being subject to simulation according to the output value of the simulator; and
controlling, by using an evaluation function, learning of a setting of a parameter value of the simulator, the evaluation function being based on the output value of the simulator, the reference output value, and the weights.

20.-22. (canceled)
